(19) United States
(12) Patent Application Publication
(10) Pub. No.: US 2026/0026076 A1
(43) Pub. Date: Jan. 22, 2026

(54) SEMICONDUCTOR DEVICES AND METHODS OF FABRICATION THEREOF

(71) Applicant: TAIWAN SEMICONDUCTOR MANUFACTURING COMPANY, LTD., Hsinchu (TW)

(72) Inventor: Sung-Hsin YANG, Tainan (TW)

(21) Appl. No.: 18/958,001

(22) Filed: Nov. 25, 2024

Related U.S. Application Data
(60) Provisional application No. 63/673,740, filed on Jul. 21, 2024.

(51) Int. Cl. H01L 29/423; H01L 29/66

(52) U.S. Cl. CPC H10D 64/518; H10D 64/017; H10D 64/514

(57) ABSTRACT

Embodiments with present disclosure provide a method for fabricating a semiconductor device with long gate lengths. A patterned photoresist layer is formed over device areas with long gate lengths to enable process uniformity and improve device density.

### CROSS-REFERENCE TO RELATED APPLICATIONS

This application claims priority to the U.S. Provisional Patent Application Ser. No. 63/673,740 filed Jul. 21, 2024, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

As device dimension reduces, there is a consistent need for improving device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor substrate according to embodiments of the present disclosure.

FIGS. 2, 2A, 2B, 2C, 3A, 3B, 4, 4A, 4B, 4C, 4D, 5A, 5B, 5C, 5D, 6A, 6B, 6C, 6D, 7A, 7B, 7C, 7D, 8A, 8B, 8C, 8D, 9A, 9B, 9C, 9D, 10A, 10B, 10C, 10D, 10E, 10F, 10G, 10H, 10I, 10J, 10K, 11, 11A, 12A, 12B, 13A, and 13B schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

In some semiconductor circuits, certain transistor devices in some areas have gate lengths which are long compared to gate lengths of other transistor devices in other areas. For example, in an input output area (I/O area), transistors may have a gate length which is longer than the gate length of transistors in, for example, a digital standard cell area or a core device area. In a digital standard cell area or core device area, the transistors may have a minimum gate length allowed by the technology. In the I/O areas, the transistors, which are input/output (I/O) devices that interface between core devices and external circuitry, may longer gate length for various reasons, for example to improve transistor noise performance or transistor matching, and/or to have different threshold voltages. Besides I/O devices, high voltage devices are also used in analog-to-digital converters (ADCs). For example, in the majority of CMOS image sensors, high performance ADCs are employed to convert amplified analog signals from a CMOS pixel array to digital output for further digital imaging processing. Fabrication of ADCs for a CMOS image sensor has its fair share of challenges, such as noise, gain errors and offset errors.

During field application in a transistor, charge carriers (electrons or holes) travelling in the channel between a source and a drain are affected as the charge carriers get trapped and de-trapped at the interfaces with gate dielectric layers. When the gate dielectric layers have more defects, the trapping and de-trapping of charge carriers become more pronounced, resulting in fluctuation in carrier mobility. The fluctuation in carrier mobility tends to generate or increase electronic noises, such as flicker noise and random telegraph signal (RTS) noise.

One of the solutions to reduce noises and errors in an ADC is to increase the gate length of the transistors in the ADC. In some embodiments, the gate length may be between 0.086 μm (86 nm) and about 24 μm (24000 nm) for balanced performance of noise/error reduction and device dimensions.

Conventionally, the transistors in an ADC are planar devices where a gate structure is disposed along one surface of a channel region. Because planar devices and multi-gate devices are fabricated using different processes, fabricating planar devices and multi-gate devices on the same substrate may be complicated and costly. To improve device performance and to streamline fabrication processes, planar high voltage devices may be replaced with multi-gate counterparts. To reliably form source/drain recesses and epitaxially grow source/drain features in the source/drain recesses, isolation structures among multi-gate high voltage devices may be needed. Because isolation structures may take up space, direct replacement of planar high voltage devices with multi-gate high voltage devices of comparable dimensions may not be appropriate. In addition, compared to core devices, high voltage devices have different feature sizes and insulation requirements due to their higher operating voltages. Even when similar fabrication processes are used to form high voltage devices and core devices on the same substrate, the difference in dimensions may create complications.

For example, when a gate replacement process is adopted, sacrificial gate stacks are first formed over fin structures on the substrate to undergo a portion of the fabrication processes and the sacrificial gate stacks are then removed and replaced by functional gate structures. To form sacrificial gate stacks, a semiconductor material layer is deposited over the substrate and a gate top hard mask layer is deposited over the semiconductor material layer. Photolithography and etch processes are then used to pattern sacrificial gate stacks of various dimensions on the substrate. After formation, the sacrificial gate stacks are capped by gate top hard mask features, which are to be removed in a subsequent process. Because a high voltage device area includes long gate devices, the sacrificial gate stack density in the core device area may be smaller than that in the high voltage device area. It has been observed that such a sacrificial gate stack density difference may result in different loading in various processes. With respect to deposition processes, it has been observed that a spin-on photoresist layer on the substrate may have a smaller thickness in the core device area and a greater thickness in the high voltage device area. This uneven photoresist layer distribution over the substrate may lead to uneven etching of the photoresist layer in different device areas. With regards to planarization processes, such as chemical mechanical polishing (CMP) processes, dishing (i.e., a local low area) may be present on the sacrificial gate stacks for long gate devices (also referred to as long sacrificial gate stacks). Dishing on long sacrificial gate stacks may cause uneven removal or damage to channel regions and source/drain regions.

The present disclosure provides methods for forming a semiconductor device that includes device areas having different gate structure densities. In some embodiments, a semiconductor device including a core device area and a high voltage device area is formed. A plurality of fin structures are formed over the core device area and the high voltage device area. In the core device area, first sacrificial gate stacks and second sacrificial gate stacks are disposed over at least one of the plurality of fin structures. The first sacrificial gate stacks are formed over the channel regions of the subsequently formed core transistors. The second sacrificial gate stacks are configured to be dummy gates adjacent to subsequently formed core transistors. In some embodiments, the first sacrificial gate stacks and the second sacrificial gate stack have gate lengths between about 16 nm and about 240 nm.

In the high voltage device area, third sacrificial gate stacks and fourth sacrificial gate stacks are disposed over the plurality of fin structures. The third sacrificial gate stacks are formed over the channel regions of the subsequently formed core high voltage transistors. The fourth sacrificial gate stacks are configured to be dummy gates adjacent to subsequently formed high voltage transistors. In some embodiments, the third sacrificial gate stacks have a gate length between about 86 nm and about 24000 nm. In some embodiments, the fourth sacrificial gate stacks have a gate length between about 86 nm and about 260 nm.

After formation of the source/regions from the fin structures, at least the first sacrificial gate stacks and the third sacrificial gate stacks will be replaced with functional gate structures. When formed, each of the sacrificial gate stacks is capped with a gate top hard mask feature. To evenly remove the gate top hard mask features, a photoresist layer is deposited over the substrate. Due to the increased dummy gate density, a portion of the photoresist layer in the high voltage device area or long gate region is thicker than a portion of the photoresist layer in the core device area. To balance the etch loading between two device areas, openings are selectively formed in the portion of the photoresist layer over the high voltage device area but not in the portion of the photoresist layer over the core device area. According to the present disclosure, such openings are formed over each of the third sacrificial gate stacks and the fourth sacrificial gate stacks. To accommodate the openings, the smaller fourth sacrificial gate stacks, each of the fourth sacrificial gate stacks of the present disclosure has a width that corresponds to a wavelength of the photolithography radiation source used to form the openings.

In some embodiments, depending on the gate lengths of the fourth sacrificial gate stacks, two or more fourth sacrificial gate stacks, belonging to neighboring transistors, may be exposed through a single opening in the photoresist layer. When two or more fourth sacrificial gate stacks are exposed through one opening, portions of isolation material, such as shallow trench isolation, disposed between the fourth sacrificial gate stacks may be removed.

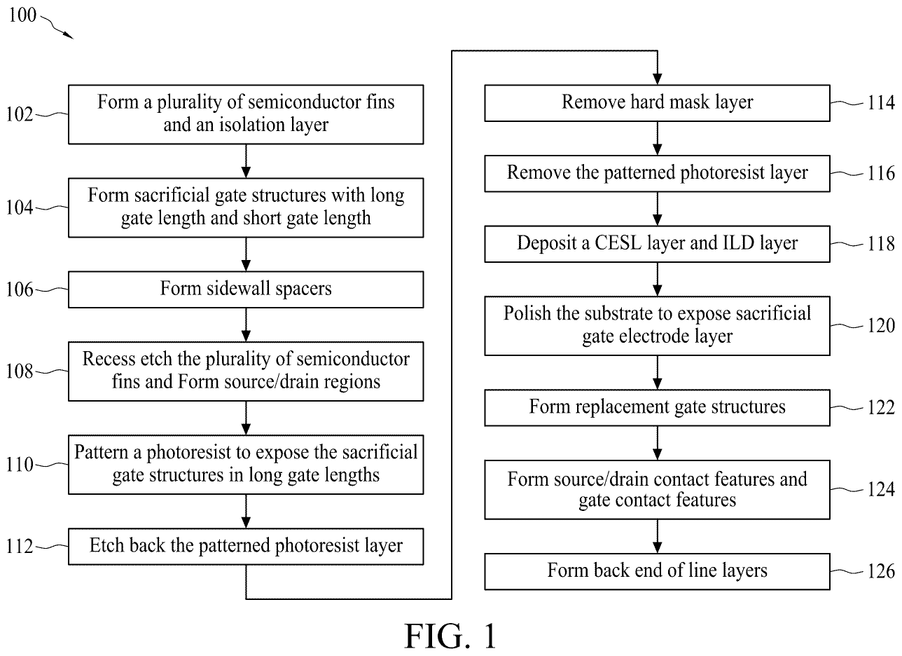

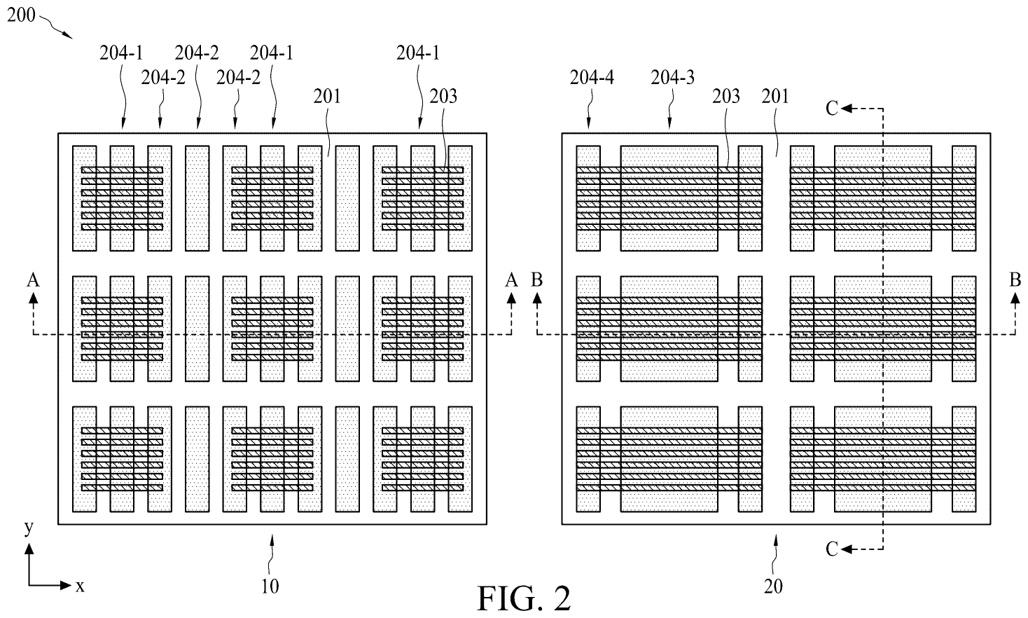

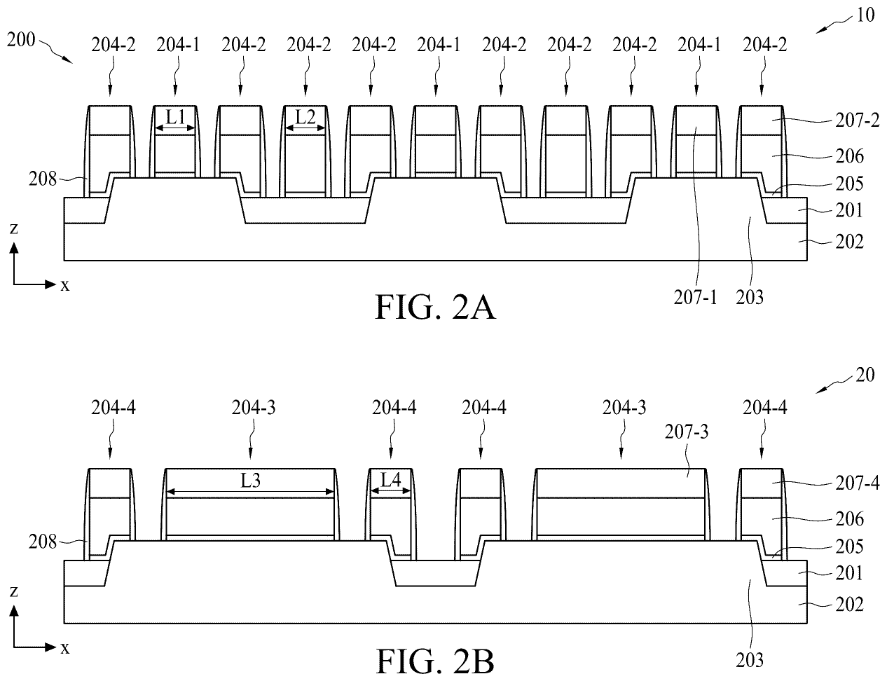

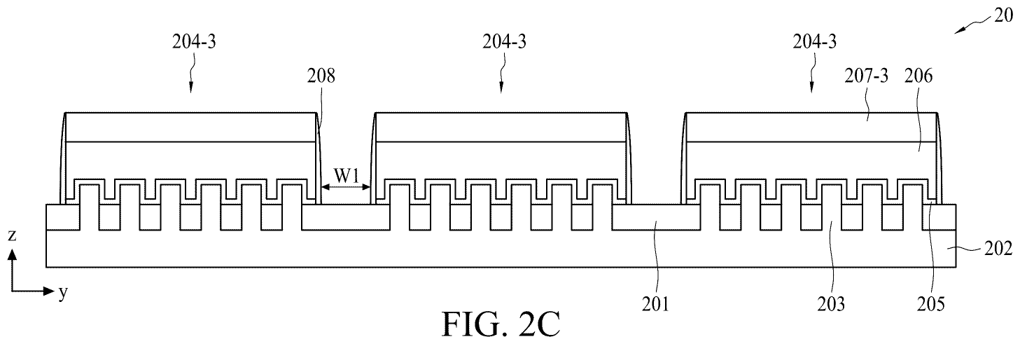

The various aspects of the present disclosure will now be described in more detail with reference to the figures. FIG. 1 is a flow chart of a method 100 for manufacturing of a semiconductor substrate according to embodiments of the present disclosure. The method 100 is merely an example and is not intended to limit the present disclosure to what is explicitly illustrated in the method 100. Additional steps can be provided before, during, and after the method 100, and some of the steps described can be moved, replaced, or eliminated for additional embodiments of the method 100. Not all steps are described herein in detail for reasons of simplicity. The method 100 will be described below in conjunction with the fragmentary top views and cross-sectional views of a workpiece shown in FIGS. 2, 2A-2C, 3A-3B, 4, 4A-4D, 5A-5D, 6A-6D, 7A-7D, 8A-8D, 9A-9D, 10A-10K, 11, 11A, and 12A-12B. Because a semiconductor device will be formed from the workpiece, the workpiece may be referred to as a semiconductor device as the context requires.

FIG. 2 is a schematic plan view of a first device area 10 and a second device area 20 of a semiconductor device 200 being processed. FIGS. 2A-2C are cross sectional views of the semiconductor device 200 along lines A-A, B-B, and C-C respectively. In some embodiments, the semiconductor device 200 is one that includes low-voltage digital functionalities in the first device area 10 and high-voltage functionalities in the second device area 20. An example of the semiconductor device 200 is an ADC that is configured to convert analog signals from an analog signal source, such as a CMOS pixel array, to digital output for further digital signal processing. In this example, the first device area 10 of the semiconductor device 200 is a digital area or a core device area while the second device area 20 of the semiconductor device 200 is an analog area or a high voltage device area. In terms of gate lengths, the semiconductor device 200 of the present disclosure includes long gate devices in the second device area 20 while the first device area 10 is free of long gate devices.

In operation 102 of the method 100, a plurality of fin structures 203 are formed in and on a substrate 202 and expand over the first device area 10 and the second device area 20 of the semiconductor device 200, as shown in FIGS. 2, 2A, 2B, and 2C.

The substrate 202 may include an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor, such as SiGe, GaAsP, AlInAs, AlGaAs, GaInAs, GaInP, GaInAsP, and/or other suitable materials. The substrate 202 may be a single-layer material having a uniform composition. Alternatively, the substrate 202 may include multiple material layers having similar or different compositions suitable for IC device manufacturing. In one example, the substrate 202 may be a silicon-on-insulator (SOI) substrate having a silicon layer formed on a silicon oxide layer. In another example, the substrate 202 may include a conductive layer, a semiconductor layer, a dielectric layer, other layers, or combinations thereof. In some embodiments where the substrate202 includes FETs, various doped regions, such as source/drain regions, are disposed in or on the substrate 202. The doped regions may be doped with p-type dopants, such as phosphorus or arsenic, and/or n-type dopants, such as boron or BF₂, depending on design requirements. The doped regions may be formed directly on the substrate 202, in a p-well structure, in an n-well structure, in a dual-well structure, or using a raised structure. Doped regions may be formed by implantation of dopant atoms, in-situ doped epitaxial growth, and/or other suitable techniques.

The plurality of fin structures 203 may be fabricated using suitable processes including photolithography and etch processes. The photolithography process may include forming a photoresist layer (resist) overlying the substrate 202, exposing the resist to a pattern, performing post-exposure bake processes, and developing the resist to form a masking element (not shown) including the resist. The masking element is then used for etching recesses into the substrate 202, leaving the plurality of fin structures 203 on the substrate 202. The etching process may include dry etching, wet etching, reactive ion etching (RIE), and/or other suitable processes. Numerous other embodiments of methods for forming the plurality of fin structures 203 may be suitable. For example, the plurality of fin structures 203 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the plurality of fin structures 203. In some embodiments, the photolithography radiation source for forming the plurality of fin structures 203 may be an extreme ultraviolet (EUV) radiation source, or an argon fluoride excimer laser radiation source with a wavelength at 193 nm. In some implementations, immersion lithography techniques may be used to form the plurality of fin structures 203. The plurality of fin structure 203 may include N fin structures, where N is between 2 and 80.

As shown in FIGS. 2, 2A, 2B, and 2C, the plurality of fin structures 203 are separated from one another by an isolation feature 201. The isolation feature 201 may include silicon oxide, silicon nitride, silicon oxynitride, fluoride-doped silicate glass (FSG), a low-k dielectric material, and/or other suitable materials. The isolation feature 201 may include shallow trench isolation (STI) features. In one embodiment, the isolation feature 201 may be formed by etching trenches in the substrate 202 during the formation of the plurality of fin structures 203. The trenches may then be filled with an isolating material described above by a deposition process, followed by a chemical mechanical planarization (CMP) process. Other isolation structures, such as field oxide, local oxidation of silicon (LOCOS), and/or other suitable structures may also be implemented as the isolation feature. Alternatively, the isolation feature 201 may include a multi-layer structure, for example, having one or more thermal oxide liner layers. The isolation feature 201 may be deposited by any suitable method, such as chemical vapor deposition (CVD), flowable CVD (FCVD), spin-on-glass (SOG), other suitable methods, or combinations thereof.

In operation 104 of the method 100, sacrificial gate stacks 204 are formed over the fin structures 203, as shown in FIGS. 2, 2A, 2B, and 2C. In the first device area 10, first sacrificial gate stacks 204-1 and second sacrificial gate stacks 204-2 are formed over the plurality of fin structures 203. In the second device area 20, third sacrificial gate stacks 204-3 and fourth sacrificial gate stacks 204-4 are formed over the plurality of fin structures 203. The sacrificial gate stacks 204-1, 204-2, 204-3, 204-4 collectively referred as sacrificial gate stacks 204.

The sacrificial gate stacks 204 are formed for a gate-last or gate replacement process is incorporated. In a gate-last process, a sacrificial gate stack is formed earlier in the fabrication process to serve as a placeholder to endure some gate-damaging process steps and is later replaced with a functional gate structure. Forming the sacrificial gate stacks 204 may include deposition of a sacrificial gate dielectric layer 205 over the fin structures 203 and the isolation feature 201. A sacrificial gate electrode layer 206 is then deposited over the sacrificial dielectric layer 205. A gate top hard mask layer 207 is the deposited over the sacrificial gate electrode layer 206. In some instances, the semiconductor material layer may include polysilicon. The gate top hard mask layer 207 may be a single layer or a multi-layer. In an example, the gate top hard mask layer 207 may include a first hard mask layer over the sacrificial gate electrode layer 206 and a second hard mask layer over the first hard mask layer. The first hard mask layer may include silicon nitride or silicon carbonitride. The second hard mask layer may include silicon oxide. Photolithography and etch processes are used to pattern the gate top hard mask layer 207. For example, a photoresist layer is deposited over the gate top hard mask layer 207, exposed to radiation transmitting through or reflected from a mask, baked in a post-exposure bake process, and developed in a developer solution to form a patterned photoresist layer.

The patterned photoresist layer is applied as an etch mask to pattern the gate top hard mask layer 207. Then the patterned gate top hard mask layer 207 is used as an etch mask to pattern the semiconductor material layer into the first sacrificial gate stacks 204-1, the second sacrificial gate stacks 204-2, the third sacrificial gate stacks 204-3, and the fourth sacrificial gate stacks 204-4. The gate top hard mask features remain on top of each of the sacrificial gate stacks. For ease of reference, these gate top hard mask features on the sacrificial gate stacks 204-1, 204-2, 204-3, 204-4 are also referred to as gate top hard mask features 207-1, 207-2, 207-3, 207-4 respectively.

The first sacrificial gate stacks 204-1, the second sacrificial gate stacks 204-2, the third sacrificial gate stacks 204-3, and the fourth sacrificial gate stacks 204-4 have different gate lengths along the X direction. The gate lengths of the sacrificial gate stacks generally correspond to the gate lengths of the gate structures.

As shown in FIGS. 2A and 2B, each of the first sacrificial gate stacks 204-1 has a first gate length L1, each of the second sacrificial gate stacks 204-2 has a second gate length L2, each of the third sacrificial gate stacks 204-3 has a third gate length L3, and each of the fourth sacrificial gate stacks 204-4 has a fourth gate length L4. As discussed above, the first sacrificial gate structures 204-1 and the second sacrificial gate structures 204-2 are configured to be replaced with functional gate structures. The second sacrificial gate structures 204-2 and the fourth sacrificial gate structures 204-4 are configured to subsequently form isolation gate structures that functions to define and restrict source/drain regions to be formed. The gate lengths L1, L2, L3, L4 are selected accordingly. Thae gate structures and isolation gate structures replacing the respectively sacrificial gate stacks have corresponding gate lengths. In some implementations, the first gate length L1 is between about 16 nm and 240 nm, the second gate length L2 is between about 16 nm and about 240 nm, the third gate length L3 is between about 86 nm and about 24000 nm, and the fourth gate length L4 is between about 86 nm and about 240 nm.

In operation 106, gate sidewall spacers 208 are formed on sidewalls of the sacrificial gate structures 204. After the sacrificial gate structures 204 are formed, the gate sidewall spacers 208 may be formed by a blanket deposition of an insulating material followed by anisotropic etch to remove insulating material from horizontal surfaces. The gate sidewall spacers 208 may have a thickness in a range between about 3 nm and about 8 nm. In some embodiments, the insulating material of the gate sidewall spacers 208 is a silicon nitride-based material, such as SiN, SiON, SiOCN or SiCN and combinations thereof.

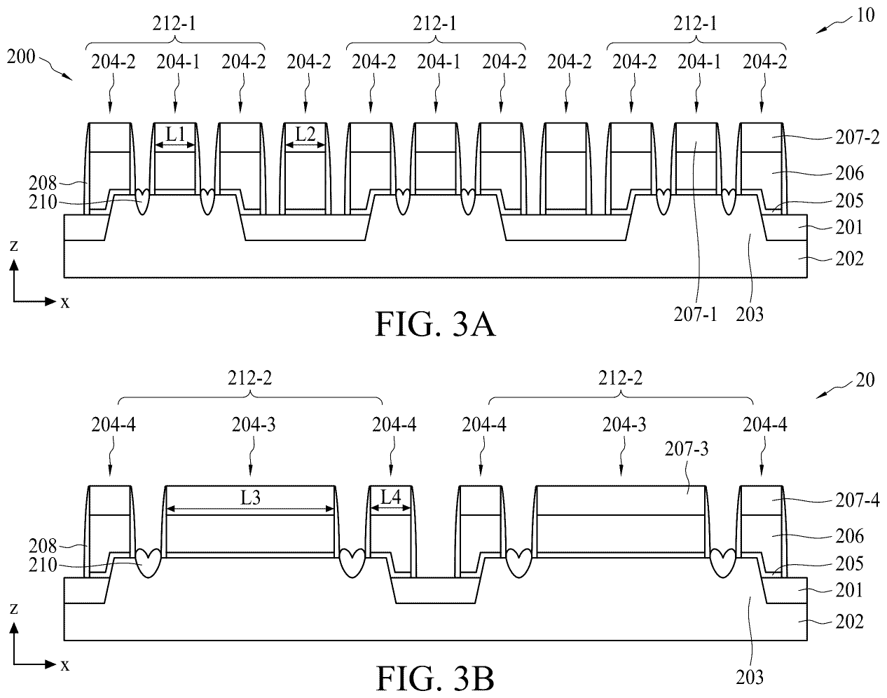

In operation 108 of the method 100, the fin structures 203 on opposite sides of the sacrificial gate structure 204 are recess etched forming source/drain recesses and then source/drain regions 210 are formed between the neighboring sacrificial gate structures 204 as shown in FIGS. 3A and 3B. FIGS. 3A and 3B are schematic cross-sectional views of the semiconductor device 200 along the A-A line and B-B line in FIG. 2 respectively.

The source/drain regions 210 may be epitaxially grown semiconductor material. In some embodiments, the source/drain regions 210 may be a composite semiconductor material including two or more semiconductor elements. In some embodiments, the source/drain regions 210 may include one or more layers of epitaxially formed semiconductor layers. The source/drain regions 210 may include one or more layers of Si, SiP, SiC and SiCP for NFET or Si, SiGe, Ge for a PFET. For the PFET, p-type dopants, such as boron (B), may also be included in the source/drain regions 210. For NFET, n-type dopants, such as arsenic (As), phosphorous (P), or carbon (C), or combinations thereof, may also be included in the source/drain regions 210.

As shown in FIG. 3A, in the first device area 10, the source/drain regions 210 are disposed adjacent both ends of the first sacrificial gate stacks 204-1 forming first transistors 212-1, which are low voltage transistors with short length gates. As shown in FIG. 3B, in the second device area 20, the source/drain regions 210 are disposed adjacent both ends of the third sacrificial gate stacks 204-3 forming second transistors 212-2, which are high voltage transistors with long length gates.

As discussed before, at least a portion of the second sacrificial gate stacks 204-2 and the fourth sacrificial gate stacks 204-4 are configured to provide structural limit for the source/drain regions 210. As shown in FIG. 3A, in some embodiments, the source/drain regions 210 in the first device area 10 are formed between the first sacrificial gate stacks 204-1 and the second sacrificial gate stacks 204-2. In some embodiments, some of the second sacrificial gate structures 204-2 may be disposed over the isolation feature 201 between neighboring first transistors 212-1. The additional second sacrificial gate stacks 204-2 between the transistors 212-1 may balance in pattern density. The source/drain regions 210 in the second device area 20 are formed between the third sacrificial gate stacks 204-3 and the fourth sacrificial gate stacks 204-4. In some embodiments, the fourth sacrificial gate structures 204-4 of neighboring second transistors 212-2 are disposed adjacent each other, with no additional fourth sacrificial gate stacks 204-4 in between, therefore reducing distance between the second transistors 212-2 in the second device area 20.

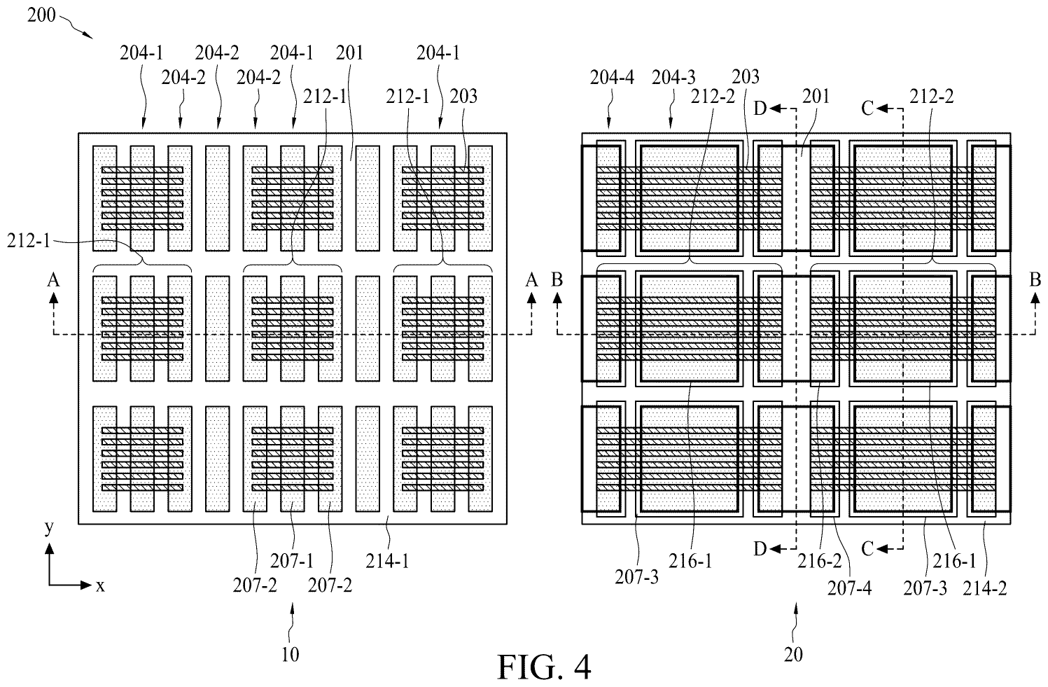

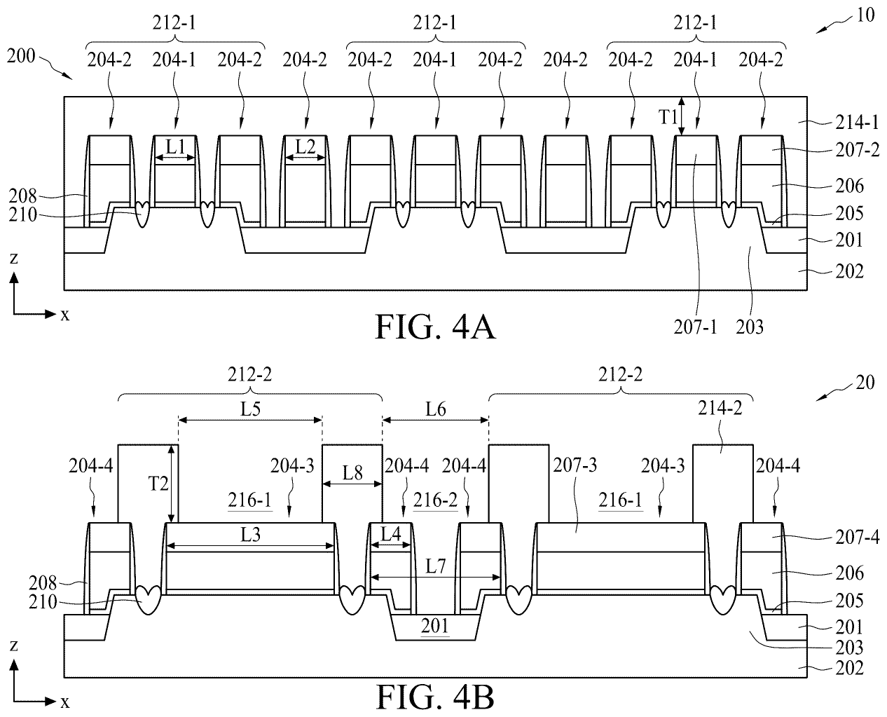

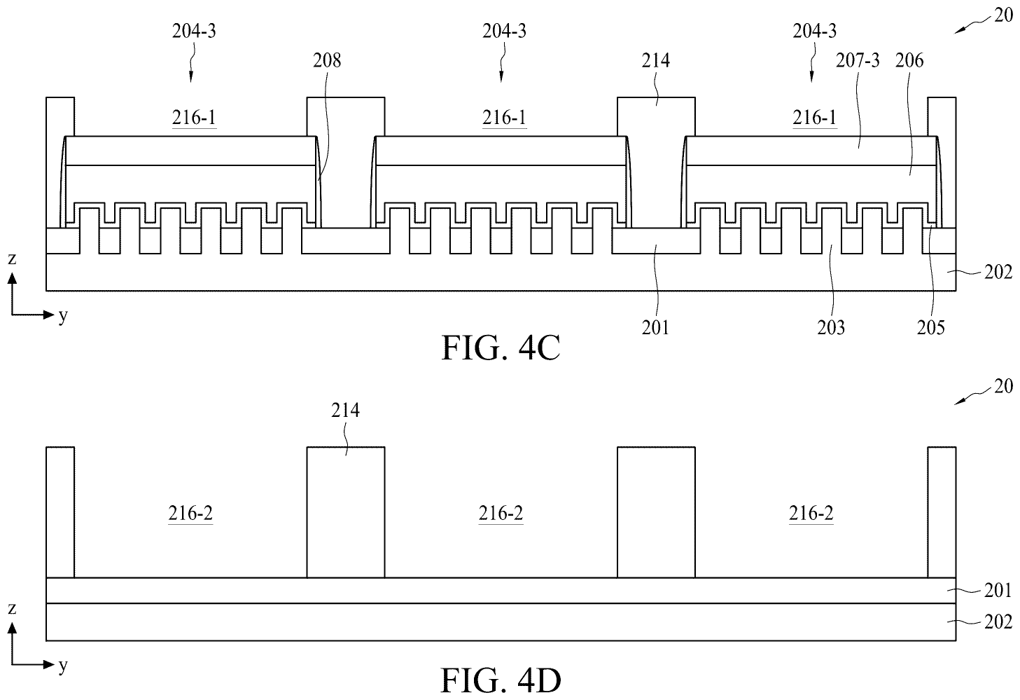

In operation 110 of the method 100, a photoresist layer 214 is deposited over the semiconductor device 200 and patterned to expose portions of the gate top hard mask features 207-3, 207-4 in the second device area 20, as shown in FIGS. 4, 4A, 4B, 4C, and 4D. FIG. 4 is a schematic top view of the semiconductor device 200. FIGS. 4A, 4B, 4C, and 4D are schematic cross sectional views along lines A-A, B-B, C-C, and D-D in FIG. 4 respectively.

As shown in FIGS. 4A and 4B, the photoresist layer 214 includes a first portion 214-1 over the first device area 10 and a second portion 214-2 over the second device area 20. In some embodiments, the long gate length of the third sacrificial gate stack 204-3 in the second device area 20 leads to a greater density of the sacrificial gate material in the second device area 20. Similarly, the lack of long gate devices in the first device area 10 has a lower density of the sacrificial gate material. It has been observed that the density of sacrificial gate material or overall area of inter sacrificial gate trenches is tied to thicknesses of the first portion 214-1 of the photoresist layer 214 and the second portion 214-2 in the photoresist layer 214.

In some embodiments, the first portion 214-1 has a first thickness T1 between about 2500 Å and about 2700 Å and the second portion 214-2 has a second thickness (T2) between about 2600 Å and about 3000 Å. The second thickness T2 is greater than the first thickness T1. In some instances, a difference between the first thickness T1 and the second thickness T2 is between about 100 Å and about 300 Å.

In current state of art technology, this thickness difference may result in photoresist layer residue over some gate top hard mask features 207 in the second device area 20. The residual photoresist layer may further lead to incomplete removal of the gate top hard mask features 207, incomplete removal of third sacrificial gate stacks 204-3 and the fourth sacrificial gate stacks 204-4, and incomplete or defective formation of gate structures. Resorting directly to planarization processes may not be an ideal solution as the long third sacrificial gate stacks 204-3 may induce dishing during CMP, which may nevertheless lead to defective gate structures.

In some embodiments, the photoresist layer 214 may be patterned in the second device area 20 to facilitate complete removal of the gate top hard mask features 207. To balance out of the difference between the first thickness T1 of the first portion 214-1 and the second thickness T2 of the second portion 214-2, openings are formed in the second portion 214-2 while the first portion 214-1 is kept intact. In some embodiments, first openings 216-1 and second openings 216-2 are formed in the photoresist layer 214-2 in the second device area 20. Particularly, the first openings 216-1 are formed over the third sacrificial gate stacks 204-3 and the second openings 216-2 are formed over the fourth sacrificial gate stacks 204-4.

In some embodiments, each of the first opening 216-1 may correspond to one third sacrificial gate stack 204-3. Each of the second openings 216-2 may correspond to two or more fourth sacrificial gate stacks 204-4 between neighboring second transistors 212-2. As shown in FIGS. 4 and 4B, each of the second openings 216-2 extends along the X-direction across the fourth sacrificial gate stacks 204-4 between two neighboring second transistors 212-2. In some embodiments, two of the fourth sacrificial gate stacks 204-4 are partially exposed to the second opening 216-2. A portion of the isolation feature 201 between the sacrificial gate stacks 204-4 is also exposed by the second opening 216-2.

In some embodiments, the first opening 216-1 has a length L5 along the X-direction. The length L5 of the first opening 216-1 is smaller than the third gate length L3 of the third sacrificial gate stacks 204-4. In some embodiments, a ratio of the length L5 over the length L3 is in a range between about 50% and about 90%.

In some embodiments, the second opening 216-2 has a length L6 along the X-direction. Since the second opening 216-2 extends along the X-direction for more than one fourth sacrificial gate stacks 204-4, the gate length L4 of the fourth sacrificial gate stacks 204 may be reduced to increase device density. All the fourth sacrificial gate stacks 204-4 between two neighboring second transistors 212-2 extend for a length L7 along the X-direction. In some embodiments, the length L7 may be about 395 nm, for example in a range between about 395 nm and about 520 nm. The length L6 of the second opening 216-2 is smaller than the length L7. In some embodiments, a ratio of the length L6 over the length L7 is in a range between about 50% and about 90%. The length L6 may be in a range between about 260 nm, for example in a range between about 260 nm and 500 nm.

In some embodiments, in the second device area 20, the patterned photoresist layer 214 covers the source/drain regions 210. In some embodiments, the patterned photoresist layer 214 may have a length L8 along the x-direction over the source/drain regions 210. The length L8 is greater than the length of the source/drain regions 210. In some embodiments, the length L8 is about 1.1 times and 2.0 times of the source/drain regions 210.

A photolithography process may be used to pattern the second portion 214-2 to form the first openings 216-1 and the second openings 216-2. At this stage, because photolithography of the fin structures 203 and the sacrificial gate stacks 204 have already been performed, the photolithography process may be a different type of photolithography process with a reduced resolution. In other words, the photolithography process may involve use of a radiation source having a wavelength greater than the wavelength of the radiation source used to form the fin structures 203 and the sacrificial gate stacks 204. For example, the radiation source for the photolithography process may be a krypton fluoride (KrF) excimer laser radiation source, which has a wavelength at about 248 nm.

To ensure that the X-direction dimension of the second opening 216-2 is smaller than the length L7, which may include as less as two fourth sacrificial gate stack 204-4 and a gap there between. In some embodiments, the length L7 may be as less as three times the fourth gate length L4. In some embodiments, the fourth gate length L4 may be substantially equal to or greater than the wavelength of the radiation source used for forming sacrificial gate stacks 204. In embodiments where the wavelength of the radiation source for the photolithography process for the photoresist layer 214 is 248 nm, the fourth gate length L4 should be around 83 nm or greater. In some embodiments, the fourth gate length L4 is about 86 nm and the length L6 of the second opening 216-2 is about 248 nm.

Patterning the photoresist layer 214 with the second opening 216-2 across two or more fourth sacrificial gate stacks 204-4 enables extending the gate length L3 of the third sacrificial gate stacks 204-3 or the functional gate structures without increasing the gate length L4 of the fourth sacrificial gate stacks 204-4 or the isolation gate structures. For example, the third gate length L3 may be in a range between about 500 nm and about 12000 nm while the fourth gate length L4 remains between about 245 nm and 260 nm.

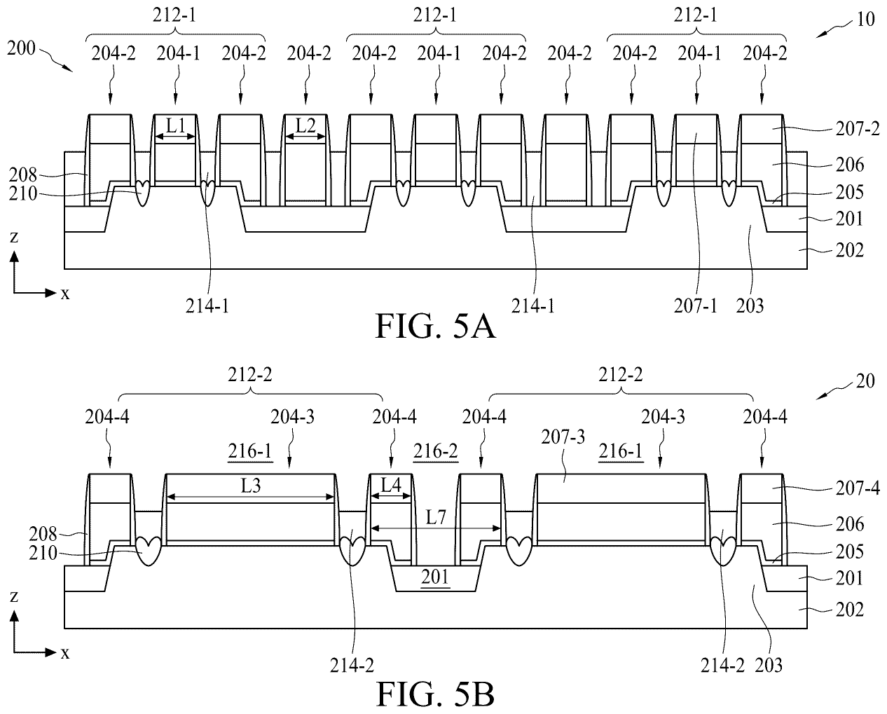

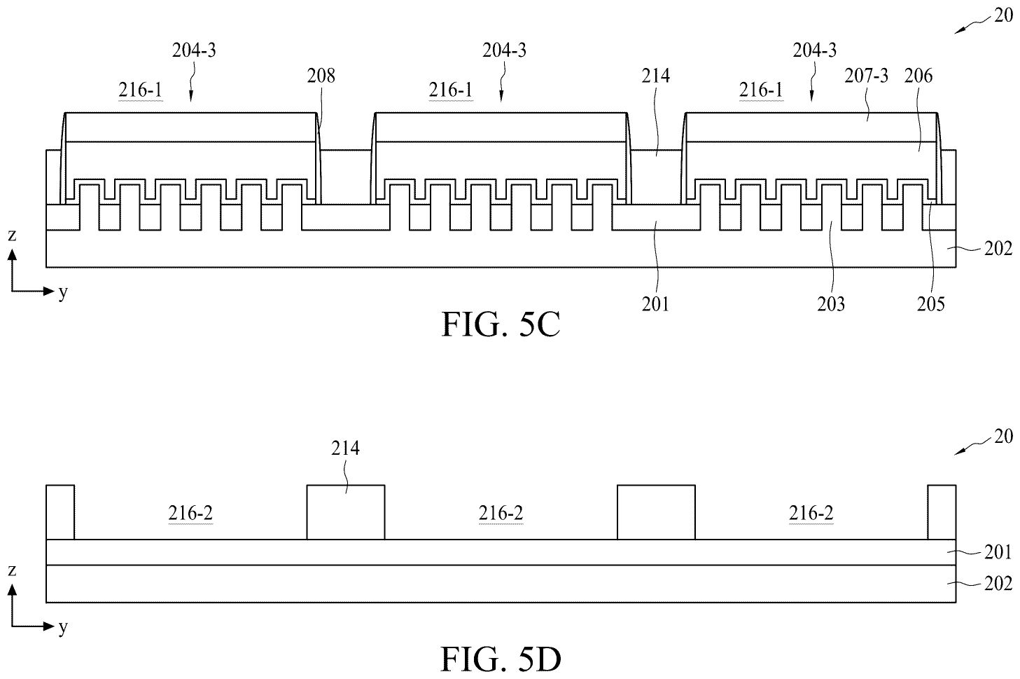

In operation 112 of the method 100, the photoresist layer 214 is etched back, as shown in FIGS. 5A-5D, which are schematic cross sectional views along lines A-A, B-B, C-C, and D-D in FIG. 4 respectively. In some embodiments, an etch back process may be performed. The etch back process may be selective to the photoresist layer 214 such that the etch back process does not substantially etch the gate top hard mask features 207. In some embodiments, the etch back process may be a dry etch process, a wet etch process, or a suitable etch process. In some embodiments, the etch back process is time-controlled such that, a top surface of the photoresist layer 214 is substantially level with a top surface of the sacrificial gate stacks on the semiconductor device 200. The residual photoresist layer 214 may protect the fin structures and the source/drain regions 210 during the subsequent processing.

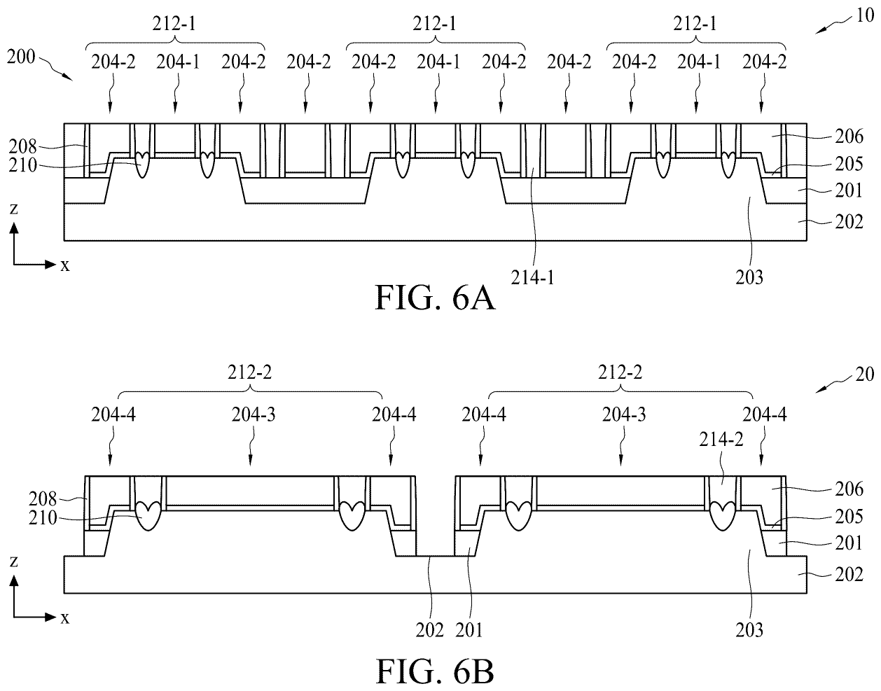

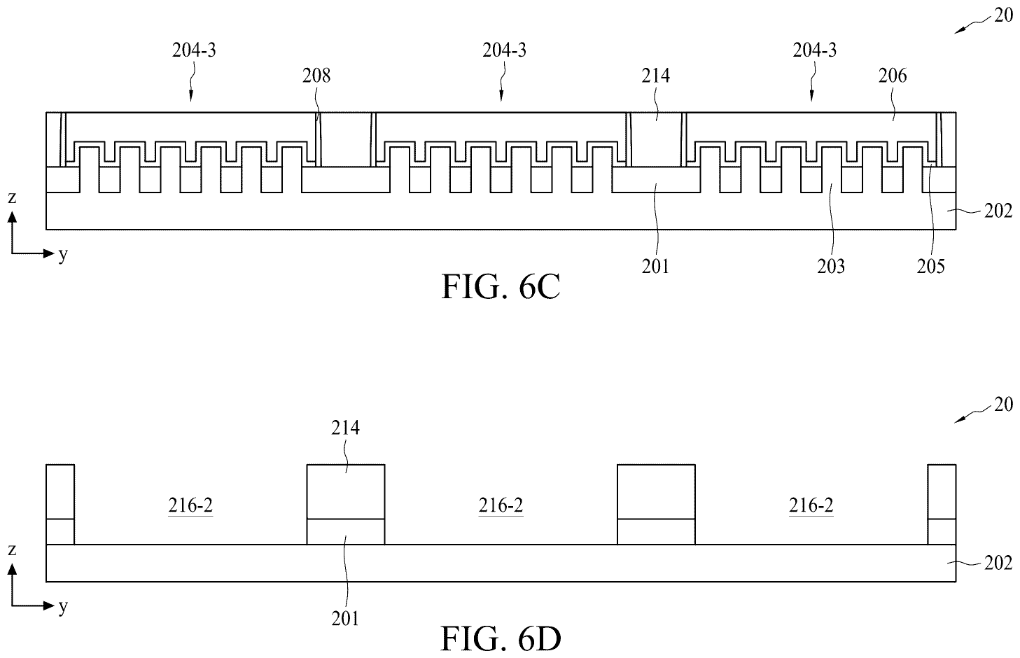

In operation 114 of the method 100, an etch process is performed to selective remove the gate top hard mask features 207 over the first device area 10 and the second device area 20, as shown in FIGS. 6A-6D, which are schematic cross sectional views along lines A-A, B-B, C-C, and D-D in FIG. 4 respectively. The etch process may be a dry etch process, a wet etch process, or a suitable etch process. The gate top hard mask features 207 are completely removed from the first device area 10 and the second device area 20 of the semiconductor device 200. The sacrificial gate electrode layer 206 is exposed. As shown in FIGS. 6B and 6D, a portion of the isolation feature 201 between the fourth sacrificial gate stacks 204-4, and a portion of the substrate 202 is exposed.

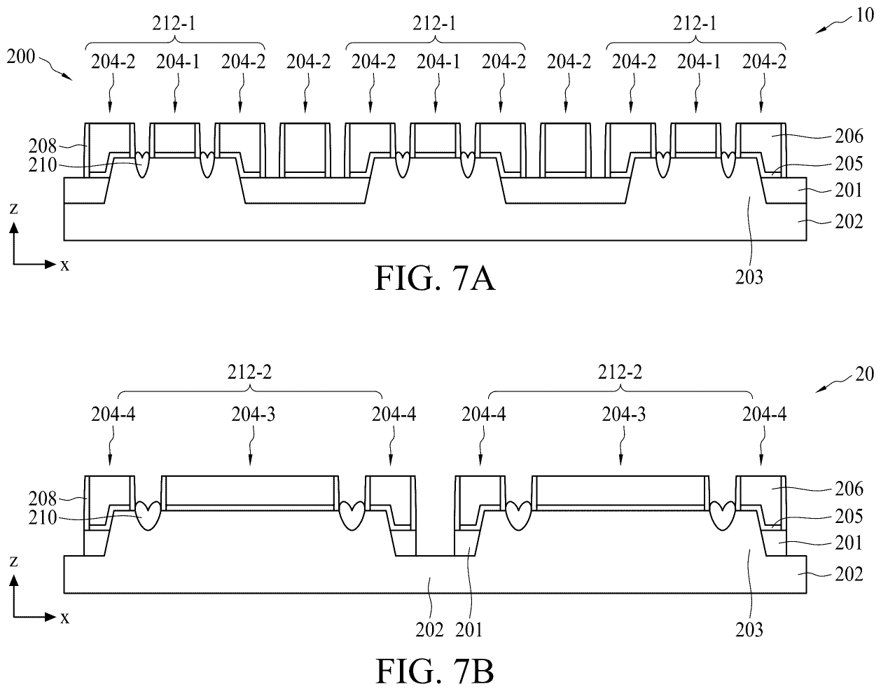

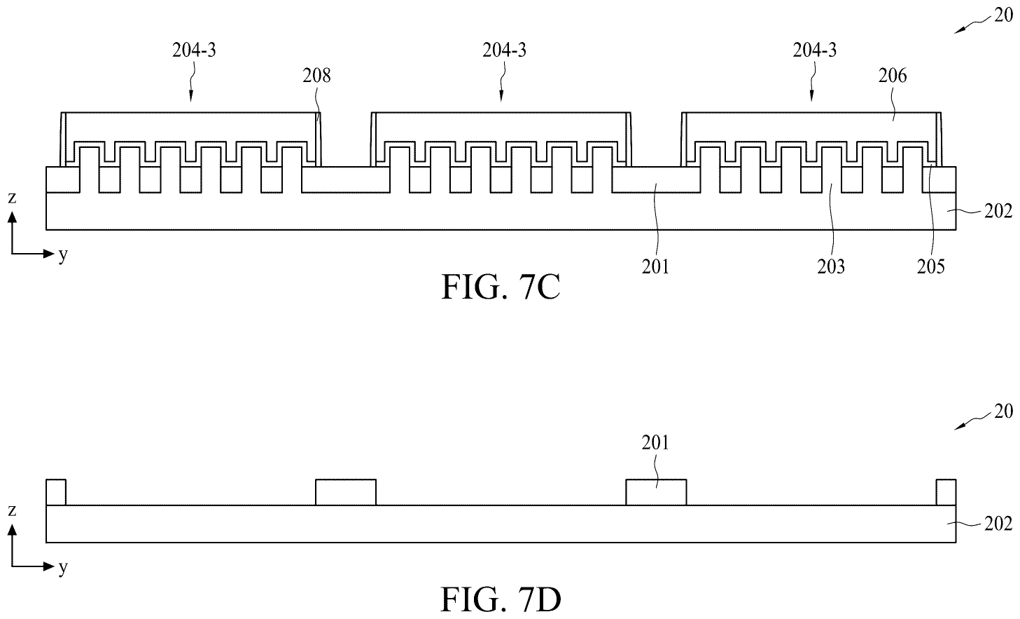

In operation 116 of the method 100, the patterned photoresist layer 214 is removed, as shown in FIGS. 7A-7D, which are schematic cross sectional views along lines A-A, B-B, C-C, and D-D in FIG. 4 respectively. In some embodiments, an ash process may be performed to remove the photoresist layer 214 and expose the source/drain regions 210.

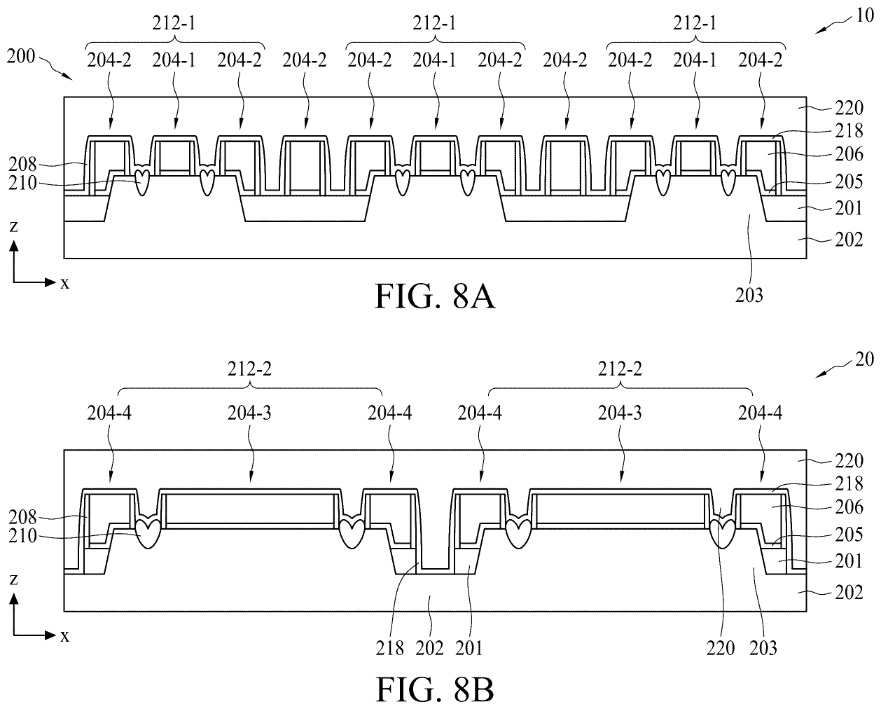

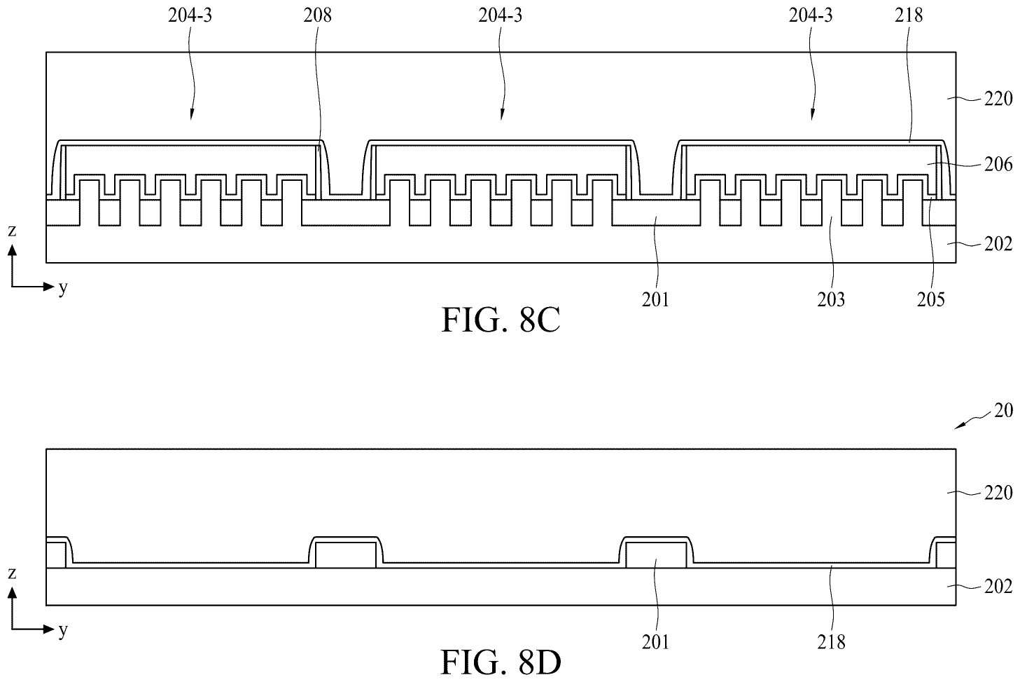

In operation 118 of the method 100, a CESL 218 and an interlayer dielectric (ILD) layer 220, as shown in FIGS. 8A-8D, which are schematic cross sectional views along lines A-A, B-B, C-C, and D-D in FIG. 4 respectively. In the first device area 10, the CESL 218 is formed on the source/drain regions 210, the gate sidewall spacers 208, the first and second sacrificial gate stacks 204-1, 204-2, and the isolation feature 201. In the second device area 20, the CESL 218 is formed on the source/drain regions 210, the gate sidewall spacers 208, the third and fourth sacrificial gate stacks 204-3, 204-4, the isolation feature 201, and the substrate 202 exposed between the fourth sacrificial gate stacks 204-4. In some embodiments, the CESL 242 has a thickness in a range between about 1 nm and about 15 nm. The CESL 242 may include Si₃N₄, SiON, SiCN or any other suitable material, and may be formed by CVD, PVD, or ALD.

The ILD layer 220 layer is deposited over the semiconductor device 200. The ILD layer 220 may include a dielectric material, such as tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), other suitable dielectric materials, or combinations thereof. In some embodiments, the ILD layer 220 may include compounds comprising Si, O, C, and/or H, such as silicon oxide, SiCOH and SiOC. In some embodiments, the ILD layer 220 includes an oxide-containing dielectric material. The ILD layer 220 may be formed by a deposition process such as, for example, CVD, flowable CVD (FCVD), spin-on-glass (SOG), other suitable methods, or combinations thereof.

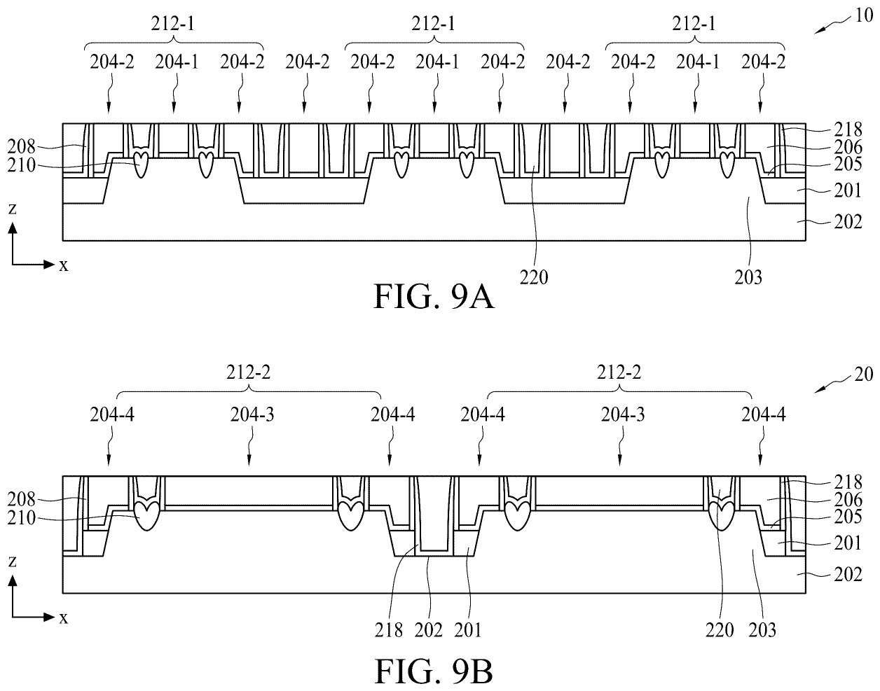

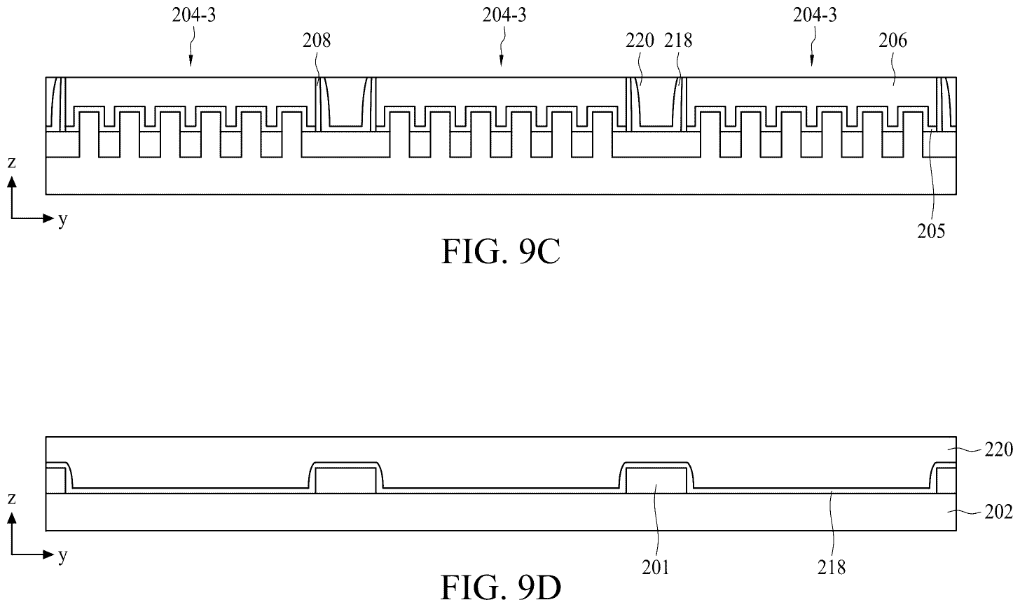

In operation 120 of the method 100, a planarization is performed to expose top surfaces of the first sacrificial gate stacks 204-1, the second sacrificial gate stacks 204-2, the third sacrificial gate stacks 204-3, and the fourth sacrificial gate stacks 204-4, as shown in FIGS. 9A-9D, which are schematic cross sectional views along lines A-A, B-B, C-C, and D-D in FIG. 4 respectively. The planarization process, such as a CMP process, may be performed to remove the portion of the ILD layer 220 over the first sacrificial gate stacks 204-1, the second sacrificial gate stacks 204-2, the third sacrificial gate stacks 204-3, and the fourth sacrificial gate stacks 204-4, thereby exposing their top surfaces. The top surfaces of the first sacrificial gate stacks 204-1, the second sacrificial gate stacks 204-2, the third sacrificial gate stacks 204-3, the fourth sacrificial gate stacks 204-4, and the ILD layer 220 are coplanar or substantially coplanar.

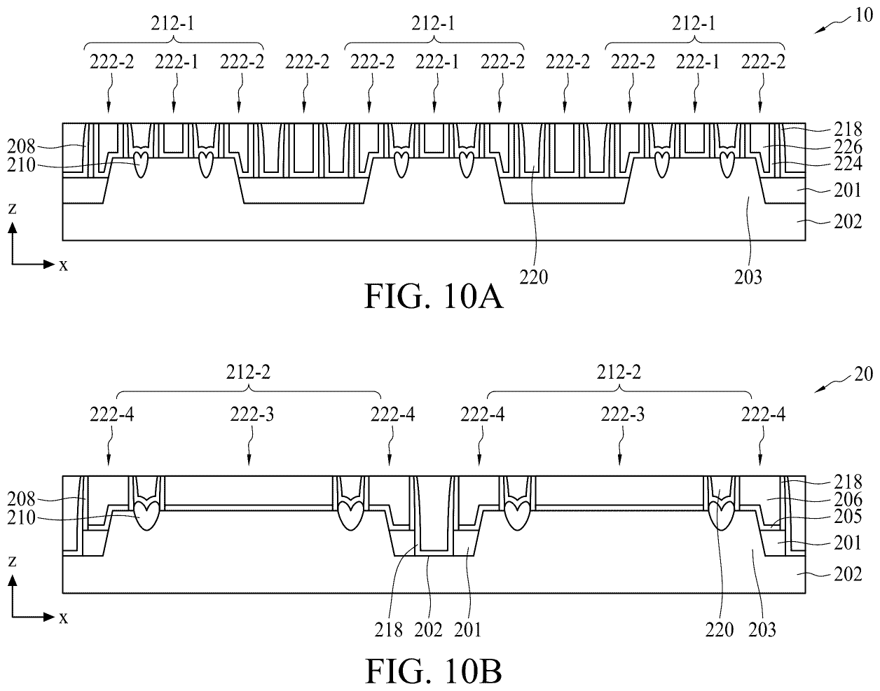

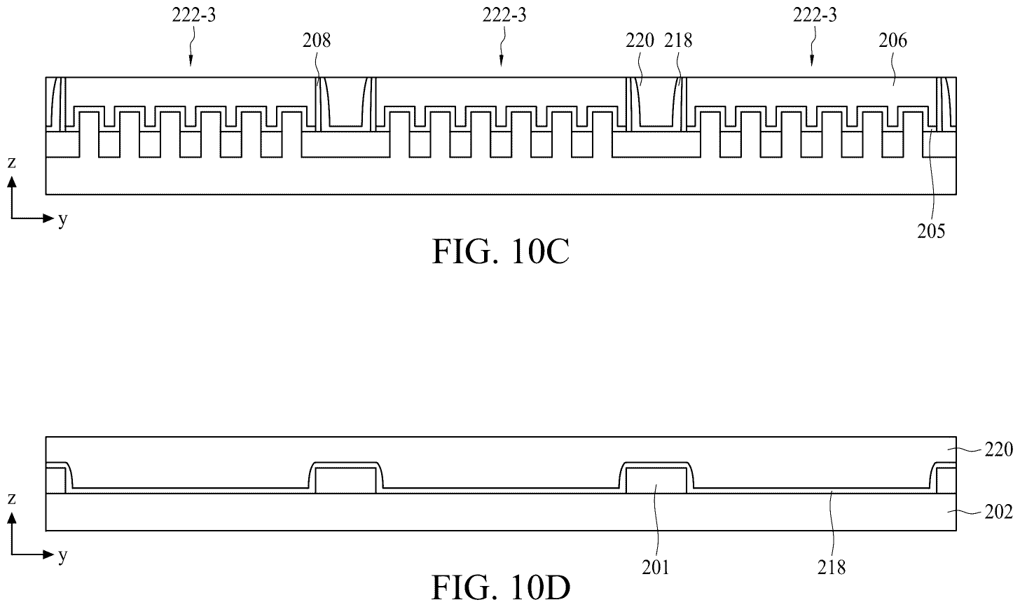

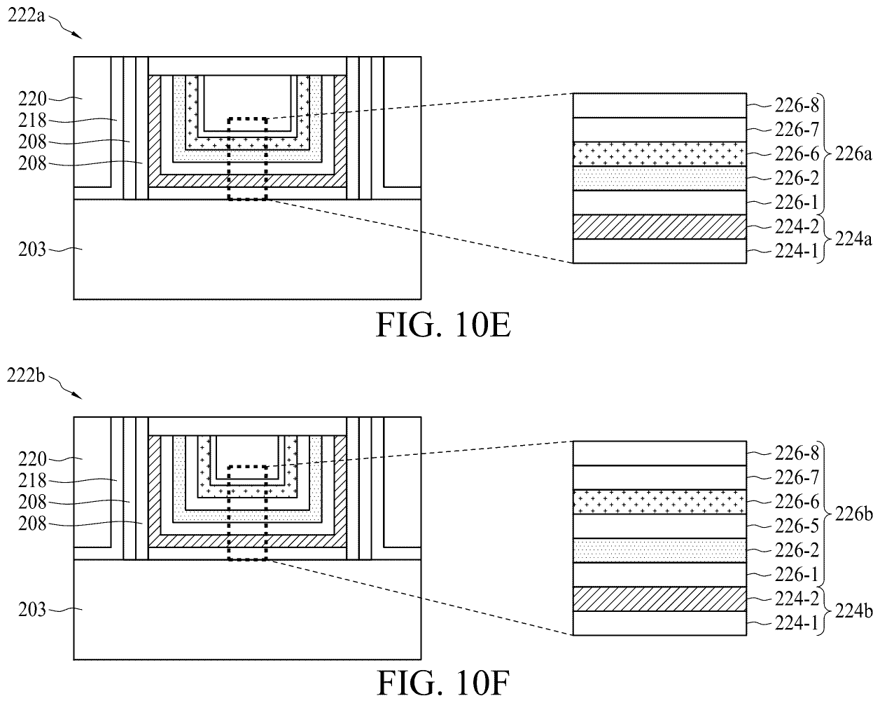

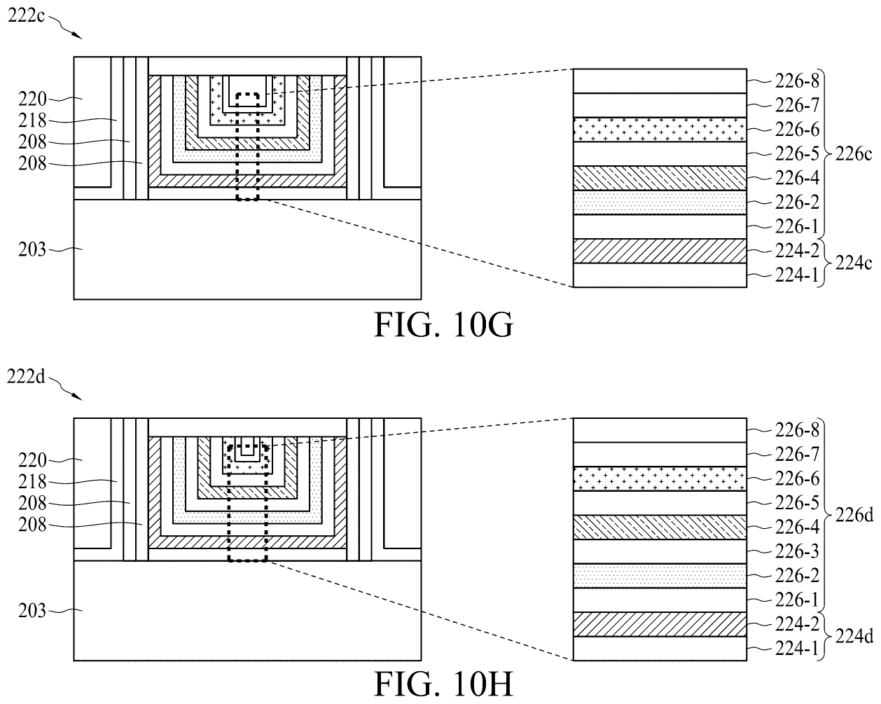

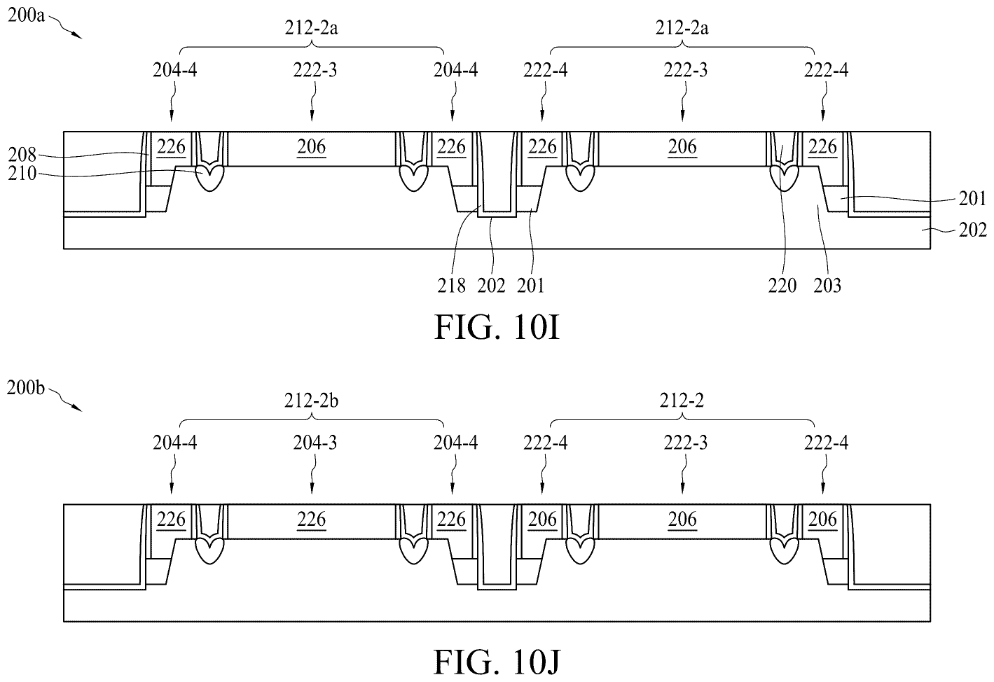

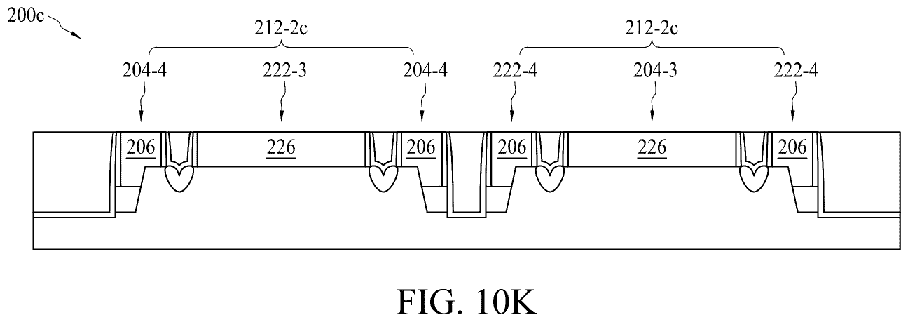

In operation 122 of the method 100, a replacement gate process is performed to replace the first sacrificial gate stacks 204-1, the second sacrificial gate stacks 204-2, the third sacrificial gate stacks 204-3, and the fourth sacrificial gate stacks 204-4 with a first gate structure 222-1, a second gate structure 222-2, a third gate structure 222-3, and a fourth gate structure 222-4, as shown in FIGS. 10A-10D, which are schematic cross sectional views along lines A-A, B-B, C-C, and D-D in FIG. 4 respectively.

The sacrificial gate stacks 204, including the first sacrificial gate stacks 204-1, the second sacrificial gate stacks 204-2, the third sacrificial gate stacks 204-3, and the fourth sacrificial gate stacks 204-4, serve as placeholders for the functional gate structures 222, such as the first gate structure 222-1 and the third gate structure 222-3, and the isolation gate structures, such as the second gate structure 222-2 and the fourth gate structure 222-4. In operation 122, the first sacrificial gate stacks 204-1, the second sacrificial gate stacks 204-2, the third sacrificial gate stacks 204-3, and the fourth sacrificial gate stacks 204-4 may be selectively etched away. In instances where the sacrificial gate electrode layer 206 includes polysilicon, an etch process that is selective to polysilicon may be used to expose the sacrificial gate dielectric layer 205. In some areas, such as the first device area 10, the sacrificial gate dielectric layer 205 may be removed to expose the plurality of fin structures 203, and form the corresponding gate structures 222 thereon. In some areas, such as the second device area 20, the sacrificial gate dielectric layer 205 may at least partially remain on the fin structures 203 serving as I/O dielectric layer in the corresponding replacement gate structures 222.

While not explicitly shown, each of the gate structures 222-1, 222-2, 222-3, 222-4 may include a gate dielectric layer 224 and a gate electrode layer 226. The gate dielectric layer 224 may include an interfacial layer on the channel region of the fin structure 203 and one or more high-k dielectric layers (i.e., having a dielectric constant greater than that of silicon oxide, which is about 3.9) over the interfacial layer. In some implementations, the interfacial layer may include silicon oxide and the high-k dielectric layer may include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, the like, or combinations thereof. The interfacial layer functions to enhance adhesion of the high-k dielectric layers to the channel region of the fin structure 203.

The gate electrode layer 226 may include at least one work function metal layer and a metal fill layer disposed thereover. Depending on the conductivity type of the semiconductor device 200, the work function metal layer may be a p-type or an n-type work function metal layer. Exemplary work function materials include TIN, TaN, Ru, Mo, AI, WN, ZrSi₂, MoSi₂, TaSi₂, NiSi₂, Ti, Ag, TaAl, TaAIC, TiAIN, TaC, TaCN, TaSiN, Mn, Zr, other suitable work function materials, or combinations thereof. The metal fill layer may include copper (Cu), tungsten (W), aluminum (AI), cobalt (Co), other suitable materials, or combinations thereof and may be deposited using physical vapor deposition (PVD), CVD, ALD, or other suitable processes. A planarization process may be performed to the semiconductor device 200 to form a planar top surface.

The gate structures 222-1, 222-2, 222-3, 222-4 may include different layers and have different dimensions to achieve different functions. During the replacement processes multiple layers may be sequentially deposited over the semiconductor device 200. One or more patterning processes may be used to selectively deposit each layer in different gate structures 222 to obtain gate structures according to the circuit design. For example, during formation of the gate dielectric layer 224, an interfacial layer 224-1 and a high-k dielectric layer 224-2. During formation of the gate electrode layer 226, a capping layer 226-1, a barrier layer 226-2, a first work function metal layer 226-3, a second work function metal layer 226-4, a third work function metal layer 226-5, a fourth work function metal layer 226-6, a metal glue layer 226-7 and a metal fill layer 226-8 may be sequentially deposited. In some embodiments, the capping layer 226-1 may be TiN. The barrier layer 226-2 may be TaN. The first work metal function layer 226-3 may be a TiN layer. The second work function metal layer 226-4 may be a TiN layer. The third work function metal layer 226-5 may be a TiN layer. The fourth work function metal layer 226-6 may be a TaAl layer. The metal glue layer 226-7 may be a TiN layer. The metal fill layer 226-8 may be a tungsten layer. Various patterns may be used between layers to achieve different layer combinations. FIGS. 10E-10H schematically illustrate various embodiments of the gate structures 222-1, 222-2, 222-3, 222-4 according to embodiments of the present disclosure.

FIG. 10E schematically illustrates a gate structure 222a according to the present disclosure. The gate structure 222a includes a gate dielectric stack 224a and a gate electrode stack 226a. The gate dielectric stack 224a includes the interfacial layer 224-1 and the high-k dielectric layer 224-2. The gate electrode stack 226a may include the capping layer 226-1, the barrier layer 226-2, the fourth work function metal layer 226-6, the metal glue layer 226-7, and the metal fill layer 226-8. The gate structure 222a may be suitable for N-type low voltage transistor (N-LVT) or N-type ultra low voltage transistor (N-uLVT).

FIG. 10F schematically illustrates a gate structure 222b according to the present disclosure. The gate structure 222b includes a gate dielectric stack 224b and a gate electrode stack 226b. The gate dielectric stack 224b includes the interfacial layer 224-1 and the high-k dielectric layer 224-2. The gate electrode stack 226b may include the capping layer 226-1, the barrier layer 226-2, the third work function metal layer 226-5, the fourth work function metal layer 226-6, the metal glue layer 226-7, and the metal fill layer 226-8. The gate structure 222b may be suitable for N-type standard voltage transistor (N-SVT) or pass gate (PG)/pull down (PD) transistors.

FIG. 10G schematically illustrates a gate structure 222c according to the present disclosure. The gate structure 222c includes a gate dielectric stack 224c and a gate electrode stack 226c. The gate dielectric stack 224c includes the interfacial layer 224-1 and the high-k dielectric layer 224-2. The gate electrode stack 226c may include the capping layer 226-1, the barrier layer 226-2, the second work function metal layer 226-4, the third work function metal layer 226-5, the fourth work function metal layer 226-6, the metal glue layer 226-7, and the metal fill layer 226-8. The gate structure 222c may be suitable for P-type standard voltage transistor (P-SVT) or pull down (PU) transistors.

FIG. 10H schematically illustrates a gate structure 222d according to the present disclosure. The gate structure 222d includes a gate dielectric stack 224d and a gate electrode stack 226d. The gate dielectric stack 224d includes the interfacial layer 224-1 and the high-k dielectric layer 224-2. The gate electrode stack 226d may include the capping layer 226-1, the barrier layer 226-2, the first work function metal layer 226-3, the second work function metal layer 226-4, the third work function metal layer 226-5, the fourth work function metal layer 226-6, the metal glue layer 226-7, and the metal fill layer 226-8. The gate structure 222c may be suitable for P-type low voltage transistor (P-LVT) or P-type ultra low voltage transistor (P-uLVT).

In some embodiments, during operation 122, a portion of the sacrificial gate stacks 204 may remain in the semiconductor device 200 along with the replacement gate structures 222. FIGS. 10I-10K schematically semiconductor devices with various gate combination.

FIG. 10I is a schematic cross section of a semiconductor device 200a according to the present disclosure. The semiconductor device 200a is similar to the semiconductor device 200 except that the fourth sacrificial gate stacks 204-04 are not replaced in operation 122 and remain in the semiconductor device 200a after the replacement gate process. The semiconductor device 200a includes transistors 212-2a with the fourth sacrificial gate stacks 204-4 as the insolation gates and the replacement gate structures 224-4 as the function gates.

FIG. 10J is a schematic cross section of a semiconductor device 200b according to the present disclosure. The semiconductor device 200b is similar to the semiconductor device 200 except that the semiconductor device 200b includes two kinds of transistors, transistor 212-2 and transistor 212-2b. The transistor 212-2 includes replacement gate structures 222-3 and 222-4 while the transistor 212-2b includes the sacrificial gate stacks 204-3 and 204-4.

FIG. 10K is a schematic cross section of a semiconductor device 200c according to the present disclosure. The semiconductor device 200c is similar to the semiconductor device 200 except that the third sacrificial gate stacks 204-03 are not replaced in operation 122 and remain in the semiconductor device 200c after the replacement gate process. The semiconductor device 200c includes transistors 212-2c with the third sacrificial gate stacks 204-3 as function gates and the replacement gate structures 224-4 as isolation gates.

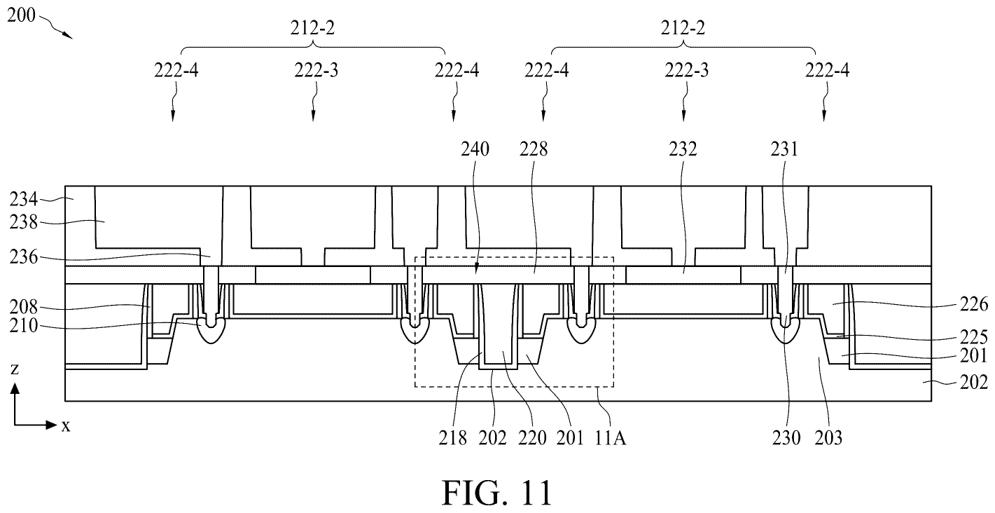

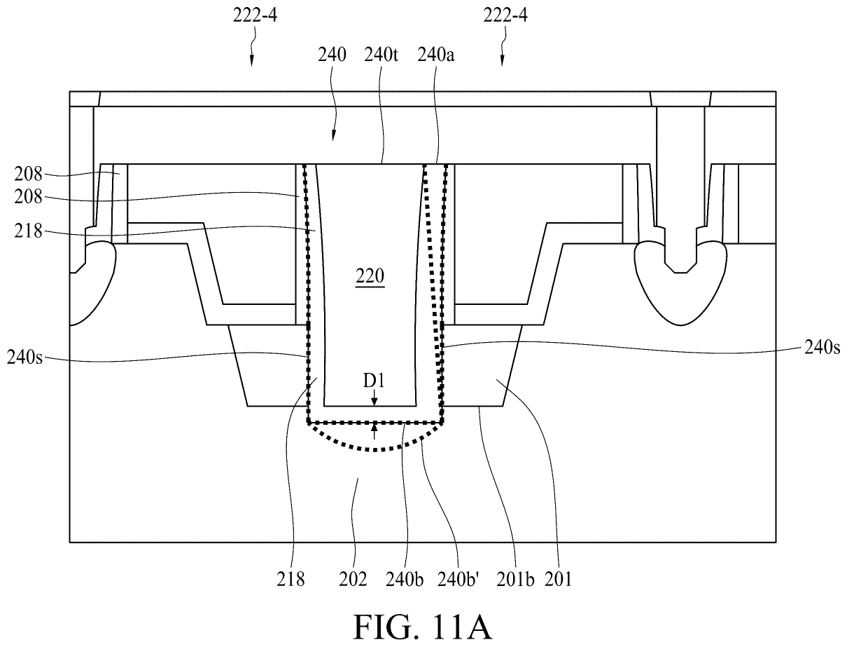

In operation 124 of the method 100, source/drain contact features 230 and gate contact features 232 are formed, as shown in FIG. 11. FIG. 11 is a cross sectional view of the semiconductor device 200 across the line B-B line of FIG. 4. The source/drain contact features 230 are formed in the ILD layer 220. Suitable photolithographic and etching techniques are used to form contact holes through various layers, including the ILD layer 220 and the CESL 218 to expose the source/drain regions 210. A silicide layer is selectively formed over exposed surfaces of the source/drain regions 210. The silicide layer may be formed by depositing a metal source layer over the semiconductor device 200 to cover the source/drain regions 210 and then performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed, for example, a rapid anneal at about 800° C. In some embodiments, the silicide layer may include one or more of WSi, CoSi, NiSi, TiSi, MoSi, and TaSi.

After the silicide layer is formed, the source/drain contact features 230 are formed in the contact holes by CVD, ALD, electro-plating, or other suitable method. The source/drain contact features 230 may include one or more of Co, Ni, W, Ti, Ta, Cu, AI, TIN and TaN. In some embodiments, a barrier layer may be formed on sidewalls of the contact holes prior to forming the source/drain contact features 230. After deposition to fill the contact holes, a planarization process, such as CMP, is performed to remove excess deposition of the contact material.

In some embodiments, a second ILD layer 228 is formed over the semiconductor device 200. Conductive features are formed in the second ILD layer 228 to provide electrical connections to the source/drain contact feature 230 and/or the gate structures 222. In some embodiments, the contact features 231 in the second ILD layer 228 are connected to the source/drain contact features 230. The gate contact features 232 are formed in the second ILD layer 228 to connect the gate electrode layer 226.

In operation 126 of the method 100, an interconnect structure may be formed over the second ILD layer 228 to further connect with the source/drain regions 210 and the gate structures 222 as shown in FIG. 11. In FIG. 11, one IMD layer 234 is shown. Conductive vias 236 and conductive lines 238 are formed in the IMD layer 234. The conductive lines 238 are connected to the source/drain contact features 230 or the gate contact features 231. Additional IMD layers are formed to complete the interconnect structure.

By patterning a photoresist layer over the gate top hard mask according to the present disclosure, the gate top hard mask layer over the short gate length dummy gates may be completed removed. The patterning method according to the present disclosure enables a shorter gate length of dummy gates near functional gates with long gate lengths. Because the photoresist layer is patterned to form a single opening across all dummy gates between two neighboring long gate transistors, the gate length of the dummy gates may be reduced, thus, increasing device density in the device. While the second opening 216-2, shown in FIG. 4, exposes a portion of the isolation feature 201, a gate isolation structure 240 is formed between the isolation gate structures, such as the gate structures 222-4, of neighboring long gate transistors 212-2.

FIG. 11A is an enlarged view of the semiconductor device 200 in the area 11A of FIG. 11. The gate isolation structure 240 is shown in detail in FIG. 11A. The gate isolation structure 240 may include the CESL layer 218 and the ILD layer 220. The gate isolation structure 240 extends from the substrate 202 to the second ILD layer 228. The CESL layer 218 extends along sidewalls 240s and a bottom surface 240b of the gate isolation structure 240. In some embodiments, a bottom surface 240b′ of the gate isolation structure 240, which is an interface between the CESL layer 218 and the substrate 202, is a curved surface. In some embodiments, the bottom surface 240b′ is higher towards the sidewalls 240s and lower near a central region. The ILD layer 220 is disposed over the CESL layer 218 and fills the gate isolation structure 240 to a top surface 240t. The top surface 240t of the gate isolation structure 240 in contact with the second ILD layer 228. In some embodiments, an etch stop layer may be disposed between the gate isolation structure 240 and the second ILD layer 228. The bottom surface 240b of the gate isolation structure 240 is below a bottom surface 201b of the isolation feature 201. The gate isolation structure 240 divides the isolation feature 201 between neighboring transistors 212-2. In some embodiments, the bottom surface 240b and the bottom surface 201b have a distance D1 along the z-direction. In some embodiments, the distance D1 is in a range between about 5 nm and 20 nm. The sidewall 240s of the gate isolation structure 240 is in contact with the substrate 202, the isolation feature 201, the gate sidewall spacer 208. In some embodiments, the sidewalls 240s of the gate isolation structure 240 are slanted resulting in a wider top portion and narrower bottom portion. In some embodiments, the sidewall 240s may be tilted related to the y-z plane. In some embodiments, the sidewalls 240s may be tilted relative to the y-z plane for an angle 240a. In some embodiments, the angle 240a may be in a range between about 5° and about 20°.

As discussed above, the semiconductor device 200 may include the first transistors 212-1 in the first device area 10 and the second transistor 212-2 in the second device area 20. Each of the first transistors 212-1 is spaced apart along the X direction from a neighboring first transistor 212-1 by at least one of the second gate structures 222-2. In some embodiments, each of the first transistors 212-1 is spaced apart along the X direction from a neighboring first transistor 212-1 by two of the second gate structures 222-2.

In some embodiments, each of the second transistors 212-2 is spaced apart along the X direction from a neighboring second transistor 212-2 by two of the fourth gate structures 222-4. One or more gate isolation structures 240 are disposed between the fourth gate structures 222-4. As described above, in embodiments where the semiconductor device 200 is an analog-to-digital converter (ADC), the first device area 10 is a digital area and the second device area 20 is an analog area. In these embodiments, the first transistor 212-1 has an operating voltage between about 0.5 V and about 0.8 V and the second transistor 212-2 has an operating voltage between about 1.8 V and about 4 V, such as between about 2.5 V and about 3.3 V.

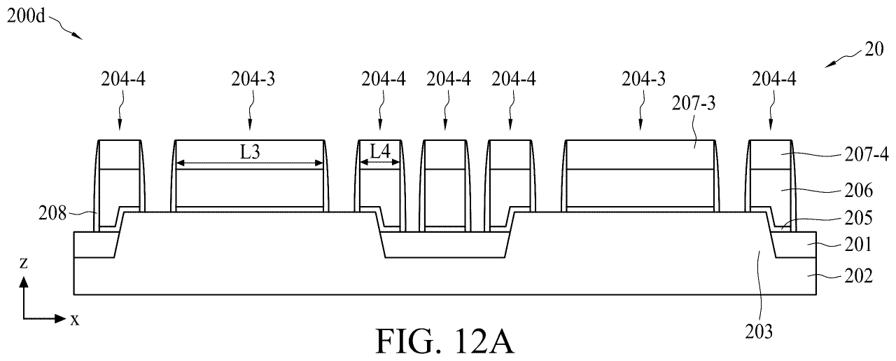

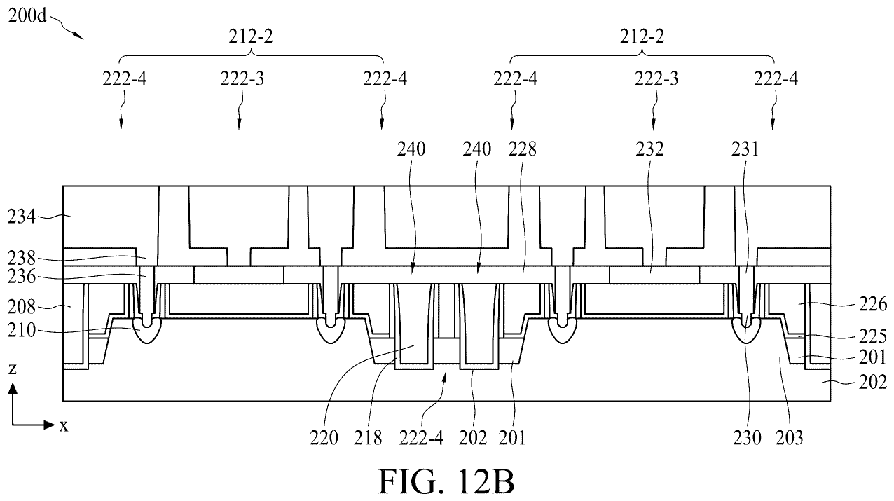

FIGS. 12A and 12B schematically illustrate a semiconductor device 200d according to embodiments of the present disclosure. The semiconductor device 200d is similar to the semiconductor device 200 except that there is an additional fourth sacrificial gate structure 204-4 between the transistors 212-2. As a result, two gate isolation structures 240 disposed between the transistors 212-2. It should be noted that less or more sacrificial gate structures 204-4 may be presented between two second transistors 212-2.

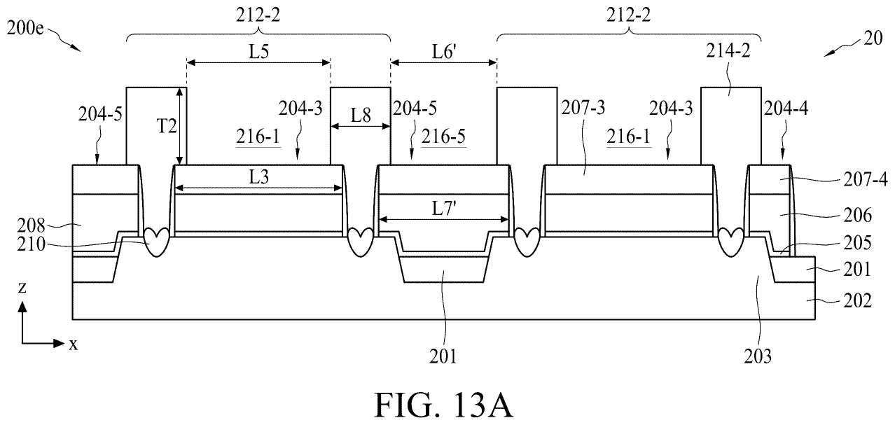

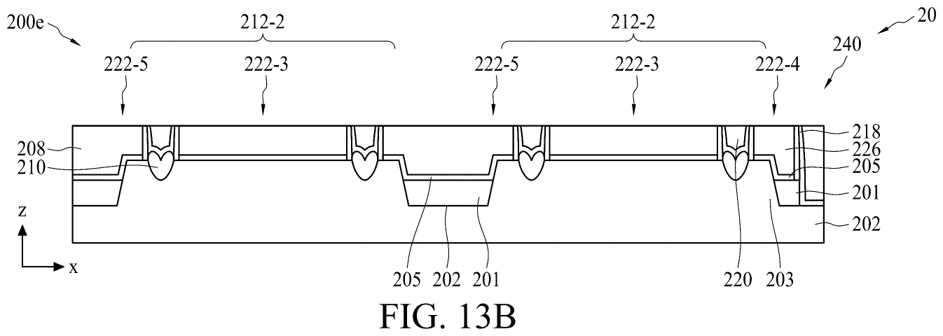

FIGS. 13A and 13B schematically illustrate a semiconductor device 200e according to embodiments of the present disclosure. The semiconductor device 200e is similar to the semiconductor device 200 except that a continuous polysilicon on oxide definition edge (CPODE) structure 204-5 is positioned between the between the transistors 212-2 in place of the fourth sacrificial gate structure 204-4. During the operation 110, the CPODE structure 204-5 are also exposed with the long sacrificial gate structures 204-3, as shown in FIG. 13A. In some embodiments, the CPODE structure 204-5 extends for a length L7′ along the X-direction. In some embodiments, the length L7′ may be about 395 nm, for example in a range between about 395 nm and about 520 nm. During operation, an opening 216-5 is formed over the CPODE structure 204-5. The opening 216-5 has a length L6′ along the X-direction. The length L6′ is smaller than the length L7′. In some embodiments, a ratio of the length L6′ over the length L7′ is in a range between about 50% and about 90%. The length L6′ may be in a range between about 260 nm, for example in a range between about 260 nm and 500 nm.

By placing the CPODE structure 204-5 between the transistors 212-2, instead of two sacrificial end gate structures, the distance between the transistors 212-2 can be reduced. As shown in FIG. 13B, a CPODE structure 222-5 is formed between the transistors 212-2 in the semiconductor 200e without any gate isolation structures 240 disposed in between. In some embodiments, the CPODE structure 222-5 may be disposed on both ends of a transistor 212-2 with long gate length, for example, as the transistor 212-2 on the left side of FIGS. 13A-13B. Alternatively, a transistor 212-2 may be disposed between the CPODE structures 222-5 and the gate structure 222-4, for example, as the transistor 212-2 on the right side of FIGS. 13A-13B. AA gate isolation structure 240 is disposed adjacent to the gate structure 222-4.

Various embodiments or examples described herein offer multiple advantages over the state-of-art technology. Embodiments of the present disclosure provide a method for fabricating a semiconductor device with long gate lengths. A patterned photoresist layer is formed over device areas with long gate lengths to enable process uniformity and improve device density.

It will be understood that not all advantages have been necessarily discussed herein, no particular advantage is required for all embodiments or examples, and other embodiments or examples may offer different advantages.

Some embodiments of the present provide a semiconductor device, comprising: a first fin structure and a second fin structure extending from a top surface of a substrate, wherein the first fin structure and second fin structure are disposed in a line along a first direction; an isolation layer disposed on the top surface of the substrate, wherein the first and second fin structures extend above the isolation layer; a first gate structure disposed over the isolation layer and across the first fin structure along a second direction; a second gate structure disposed over the isolation layer across the second fin structure along the second direction; and a gate isolation structure disposed along the second direction between the first fin structure and the second fin structure, wherein the gate isolation structure has a first sidewall facing the first fin structure, a second sidewall facing the second fin structure, a bottom surface connecting the first sidewall and the second sidewall, the bottom surface is in contact with the substrate, and the bottom surface of the gate isolation structure is disposed below the top surface of the substrate.

Some embodiments provide a method for forming a semiconductor device comprising: a first device area on a substrate comprising: two or more first transistors, wherein each of the first transistors comprises: a first fin structure disposed along a first direction; and a first gate structure disposed across the first fin structure, wherein the first gate structure has a first gate length along the first direction; and a second device area on the substrate comprising two or more second transistors, wherein each of the second transistors comprises: a second fin structure disposed along the first direction; and a second gate structure disposed across the second fin structure, wherein the second gate structure has a second gate length along the first direction; and two third gate structures disposed across the second fin structure, wherein the third gate structures have a third gate length along the first direction, the third gate structures are disposed on ends of the second fin structure, and the second gate structure is disposed between the two third gate structures, wherein a ratio of the first gate length over the third gate length is between about 0.07 and about 1.0, a ratio of the second gate length over the third gate length is in a range between about 0.3 and about 50.

Some embodiments of the present provide a method comprising: forming a first fin structure and a second fin structure along a line on a substrate, wherein the first fin structure has a first end and a second end, and the second fin structure has a third end and a fourth end; depositing an isolation material on the substrate; etching back the isolation material below the first fin structure and second fin structure to form an isolation feature; forming first sacrificial gate stacks and second sacrificial gate stacks across the first and second fin structures, wherein each of the first and second sacrificial gate stacks comprises a sacrificial gate dielectric layer, a sacrificial gate electrode layer, and a gate top mask layer, the first sacrificial gate stacks are disposed between the first end and second end of the first fin structure and between the third end and fourth end of the second fin structures, and the second sacrificial gate stacks are formed on the first end and second end of the first fin structure and on the third end and fourth end of the second fin structure; forming source/drain regions between the first and second sacrificial gate stacks; depositing a photoresist layer over the first and second sacrificial gate stacks; patterning the photoresist layer to form first openings and a second opening, wherein the first openings correspond to the first sacrificial gate stacks, and the second opening extends across the second sacrificial gate stacks on the second end of the first fin structure and the third end of the second fin structure; etching back the patterned photoresist layer to expose the gate top mask layer; performing an etch process to remove the gate top mask layer and the isolation feature between the second sacrificial gate stacks, wherein a portion of the substrate is exposed between the second sacrificial gate stacks; removing the photoresist layer; depositing a contact etch stop layer on the source/drain regions and the portion of the substrate exposed between the second sacrificial gate stacks; and depositing an interlayer dielectric layer over the contact etch stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first fin structure and a second fin structure extending from a top surface of a substrate, wherein the first fin structure and second fin structure are disposed in a line along a first direction;
an isolation layer disposed on the top surface of the substrate, wherein the first and second fin structures extend above the isolation layer;
a first gate structure disposed over the isolation layer and across the first fin structure along a second direction;
a second gate structure disposed over the isolation layer across the second fin structure along the second direction; and
a gate isolation structure disposed along the second direction between the first fin structure and the second fin structure, wherein the gate isolation structure has a first sidewall facing the first fin structure, a second sidewall facing the second fin structure, a bottom surface connecting the first sidewall and the second sidewall, the bottom surface is in contact with the substrate, and the bottom surface of the gate isolation structure is disposed below the top surface of the substrate.

2. The semiconductor device of claim 1, wherein the first gate structure is in contact with the first sidewall of the gate isolation structure and the second gate structure is in contact with the second sidewall of the gate isolation structure.

3. The semiconductor device of claim 2, wherein the first fin structure has a first end and a second end, the second fin structure has a third end and a fourth end, the second end of the first fin structure faces the third end of the second fin structure, the first gate structure is disposed over the second end of the first fin structure, and the second gate structure is disposed over the third end of the second fin structure.

4. The semiconductor device of claim 3, further comprising:
a third gate structure disposed across the first fin structure between the first end and the second end;
a first source/drain region disposed between the first and third gate structures;
a fourth gate structure disposed across the second fin structure between the third end and the fourth end;
a second source/drain region disposed between the second and fourth gate structures;
a contact etch stop layer disposed over the first and second source/drain regions; and
an interlayer dielectric layer disposed over the contact etch stop layer.

5. The semiconductor device of claim 4, wherein the gate isolation structure comprises:
the contact etch stop layer disposed on the first and second sidewalls and the bottom surface; and
the interlayer dielectric layer disposed over the contact etch stop layer.

6. The semiconductor device of claim 4, wherein the first gate structure has a first gate length along the first direction, the third gate structure has a second gate length along the first direction, the first gate length is about 260 nm and the second gate length is in a range between about 500 nm and 12000 nm.

7. The semiconductor device of claim 1, wherein the first sidewall and the second sidewall are tilted, and the gate isolation structure is narrower near the bottom surface and wider near a top surface.

8. A semiconductor device, comprising:
a first device area on a substrate comprising:
two or more first transistors, wherein each of the first transistors comprises:
a first fin structure disposed along a first direction; and
a first gate structure disposed across the first fin structure,
wherein the first gate structure has a first gate length along the first direction; and
a second device area on the substrate comprising two or more second transistors, wherein each of the second transistors comprises:
a second fin structure disposed along the first direction; and
a second gate structure disposed across the second fin structure, wherein the second gate structure has a second gate length along the first direction; and
two third gate structures disposed across the second fin structure, wherein the third gate structures have a third gate length along the first direction, the third gate structures are disposed on ends of the second fin structure, and the second gate structure is disposed between the two third gate structures,
wherein a ratio of the first gate length over the third gate length is between about 0.07 and about 1.0, a ratio of the second gate length over the third gate length is in a range between about 0.3 and about 50.

9. The semiconductor device of claim 8, wherein the first gate length is in a range between about 16 nm and about 240 nm.

10. The semiconductor device of claim 9, wherein the third gate length is between about 245 nm and 260 nm.

11. The semiconductor device of claim 10, wherein the second gate length is in a range between about 86 nm and about 12000 nm.

12. The semiconductor device of claim 8, wherein the second device area further comprising:
a first gate isolation structure disposed between the two or more second transistors, wherein the first gate isolation structure has a sidewall in contact with the third gate structure of a first one of the two or more second transistors, a bottom surface in contact with the substrate.

13. The semiconductor device of claim 12, wherein each of the second transistors further comprises:
first and second source/drain regions disposed between the second gate structure and the two third gate structures;
a contact etch stop layer disposed over the first and second source/drain regions; and
an interlayer dielectric layer disposed on the contact etch stop layer,
wherein the first gate isolation structure is formed by the contact etch stop layer and the interlayer dielectric layer.

14. The semiconductor device of claim 12, wherein the second device area further comprising:
a second gate isolation structure in contact with a second one of the two or more second transistors; and
a fourth gate structure disposed between the first and second gate isolation structures.

15. A method, comprising:
forming a first fin structure and a second fin structure along a line on a substrate, wherein the first fin structure has a first end and a second end, and the second fin structure has a third end and a fourth end;
depositing an isolation material on the substrate;
etching back the isolation material below the first fin structure and second fin structure to form an isolation feature;
forming first sacrificial gate stacks and second sacrificial gate stacks across the first and second fin structures, wherein each of the first and second sacrificial gate stacks comprises a sacrificial gate dielectric layer, a sacrificial gate electrode layer, and a gate top mask layer, the first sacrificial gate stacks are disposed between the first end and second end of the first fin structure and between the third end and fourth end of the second fin structures, and the second sacrificial gate stacks are formed on the first end and second end of the first fin structure and on the third end and fourth end of the second fin structure;
forming source/drain regions between the first and second sacrificial gate stacks;
depositing a photoresist layer over the first and second sacrificial gate stacks;
patterning the photoresist layer to form first openings and a second opening, wherein the first openings correspond to the first sacrificial gate stacks, and the second opening extends across the second sacrificial gate stacks on the second end of the first fin structure and the third end of the second fin structure;
etching back the patterned photoresist layer to expose the gate top mask layer;
performing an etch process to remove the gate top mask layer and the isolation feature between the second sacrificial gate stacks, wherein a portion of the substrate is exposed between the second sacrificial gate stacks;
removing the photoresist layer;
depositing a contact etch stop layer on the source/drain regions and the portion of the substrate exposed between the second sacrificial gate stacks; and
depositing an interlayer dielectric layer over the contact etch stop layer.

16. The method of claim 15, wherein the first sacrificial gate stacks have a first gate length, the second sacrificial gate stacks have a second gate length, the first gate length is between about 86 nm and about 12000 nm, and the second gate length is between about 245 nm and 260 nm.

17. The method of claim 16, wherein the second opening has a length in a range between about 260 nm and 500 nm.

18. The method of claim 17, further comprising:
forming a third fin structure simultaneously with forming the first and second fin structure;
forming third sacrificial gate stacks simultaneously with forming the first and second sacrificial gate stacks, wherein the patterned photoresist layer covers the third sacrificial gate stacks, and the third sacrificial gate stacks have a third gate length, wherein the third gate length is in between about 16 nm and 245 nm.

19. The method of claim 15, further comprising:
removing the first sacrificial gate stacks; and
depositing a gate dielectric layer; and
depositing a gate electrode layer.

20. The method of claim 19, further comprising keeping the third sacrificial gate stacks while removing the first sacrificial gate stacks.
